(19) United States
(12) Patent Application Publication
(10) Pub. No.: US 2013/0264919 A1
(43) Pub. Date: Oct. 10, 2013

(54) SYSTEMS AND METHODS FOR MOUNTING DYNAMICALLY MODULAR PROCESSING UNITS

(71) Applicant: Jason A. Sullivan, Youngstown, OH (US)

(72) Inventor: Jason A. Sullivan, Youngstown, OH (US)

(21) Appl. No.: 13/628,022

(22) Filed: Sep. 26, 2012

Related U.S. Application Data
(63) Continuation-in-part of application No. 13/342,199, filed on Jan. 2, 2012.
Application No. 13/342,199 is a continuation-in-part of application No. 13/154,325, filed on Jun. 6, 2011.
Application No. 13/154,325 is a continuation-in-part of application No. 12/795,439, filed on Jun. 7, 2010.
(60) Provisional application No. 61/539,474, filed on Sep. 27, 2011.

(51) Int. Cl. H05K 7/14; H05K 5/02

(52) U.S. Cl. CPC H05K 7/14; H05K 5/0204
USPC 312/223.2

(57) ABSTRACT

Systems and methods for mounting a modular processing unit that is configured to be selectively used alone or with other processing units in an enterprise. A modular processing unit is provided as a platform that is lightweight, compact, and is configured to be selectively used alone or oriented with one or more additional processing units (including base modules and/or peripheral modules) in an enterprise. The one or more processing units are dynamically mounted based upon the particular enterprise needed and corresponding environment. In at least some implementations, shock mounting is included to provide for needed shock and vibe requirements. In some implementations, the mounting system includes a fixed mounting system for environments that need to be fixably secured. In other implementations, a selectively releasable connector is provided to allow for ease in mounting and removing the dynamically modular processing unit. In other implementations, a press-fit connector is provided to allow for ease in mounting and removing the dynamically modular processing unit.

### RELATED APPLICATIONS

This application claims priority to U.S. Provisional Patent Application Ser. No. 61/539,474, filed Sep. 27, 2011, entitled, “SYSTEMS AND METHODS FOR MOUNTING DYNAMICALLY MODULAR PROCESSING UNITS” (Attorney Docket No. 11072.441) and is a continuation-in-part of U.S. patent application Ser. No. 13/342,199 filed Jan. 2, 2012, entitled “SYSTEMS AND METHODS FOR PROVIDING RESOURCES AND INTERACTIVITY IN COMPUTER SYSTEMS” (Attorney Docket No. 11072.453), which is a continuation-in-part of U.S. patent application Ser. No. 13/154,325 filed Jun. 6, 2011, entitled “SYSTEMS AND METHODS FOR PROVIDING A UNIVERSAL COMPUTING SYSTEM” (Attorney Docket No. 11072.435), which is a continuation-in-part of U.S. patent application Ser. No. 12/795,439 filed Jun. 7, 2010, entitled “SYSTEMS AND METHODS FOR PROVIDING A ROBUST COMPUTER PROCESSING UNIT,” which claims priority to U.S. patent application Ser. No. 11/827,360, which was filed on Jul. 9, 2007 and entitled “SYSTEMS AND METHODS FOR PROVIDING A ROBUST COMPUTER PROCESSING UNIT,” and issued on Jun. 8, 2010 as U.S. Pat. No. 7,733,635, which claims priority to U.S. patent application Ser. No. 10/692,005, which was filed on Oct. 22, 2003 and entitled “ROBUST CUSTOMIZABLE COMPUTER PROCESSING SYSTEM,” and which issued on Jul. 10, 2007 as U.S. Pat. No. 7,242,574, which claims priority to U.S. Provisional Patent Application Ser. No. 60/420,127, filed Oct. 22, 2002, entitled, “NON-PERIPHERALS PROCESSING CONTROL UNIT HAVING IMPROVED HEAT DISSIPATING PROPERTIES” and also claims priority to U.S. Provisional Patent Application Ser. No. 60/455,789, filed Mar. 19, 2003, entitled, “SYSTEMS AND METHODS FOR PROVIDING A DURABLE AND DYNAMICALLY MODULAR PROCESSING UNIT,” which are all expressly incorporated herein by reference in their entireties.

U.S. patent application Ser. No. 13/154,325 filed Jun. 6, 2011, entitled “SYSTEMS AND METHODS FOR PROVIDING A UNIVERSAL COMPUTING SYSTEM” (Attorney Docket No. 11072.435) is also a continuation-in-part of U.S. patent application Ser. No. 12/843,304, filed Jul. 26, 2010, entitled “SYSTEMS AND METHODS FOR PROVIDING A DYNAMICALLY MODULAR PROCESSING UNIT,” which claims priority to U.S. patent application Ser. No. 11/483,956 filed Jul. 10, 2006, entitled “SYSTEMS AND METHODS FOR PROVIDING A DYNAMICALLY MODULAR PROCESSING UNIT,” which is a divisional application of U.S. patent application Ser. No. 10/691,114 filed Oct. 22, 2003, entitled “SYSTEMS AND METHODS FOR PROVIDING A DYNAMICALLY MODULAR PROCESSING UNIT,” now issued as U.S. Pat. No. 7,075,784 which claims priority to U.S. Provisional Patent Application Ser. No. 60/420,127 filed Oct. 22, 2002 entitled “NON-PERIPHERALS PROCESSING CONTROL UNIT HAVING IMPROVED HEAT DISSIPATING PROPERTIES” and to U.S. Provisional Patent Application Ser. No. 60/455,789 filed Mar. 19, 2003 entitled “SYSTEMS AND METHODS FOR PROVIDING A DURABLE AND DYNAMICALLY MODULAR PROCESSING UNIT,” which are all incorporated herein by reference, and is related to issued U.S. Pat. No. 7,256,991 filed Oct. 22, 2003, entitled “NON-PERIPHERALS PROCESSING CONTROL MODULE HAVING IMPROVED HEAT DISSIPATING PROPERTIES”, and is related to issued U.S. Pat. No. 7,242,574 filed Oct. 22, 2003, entitled “ROBUST CUSTOMIZABLE COMPUTER PROCESSING SYSTEM”, which are all expressly incorporated herein by reference in their entireties.

U.S. patent application Ser. No. 13/154,325 filed Jun. 6, 2011, entitled “SYSTEMS AND METHODS FOR PROVIDING A UNIVERSAL COMPUTING SYSTEM” (Attorney Docket No. 11072.435) is also a continuation in part of U.S. patent application Ser. No. 12/906,836 filed Oct. 18, 2010, entitled “NON-PERIPHERALS PROCESSING CONTROL MODULE HAVING IMPROVED HEAT DISSIPATING PROPERTIES”, which claims priority to U.S. patent application Ser. No. 11/833,852, filed Aug. 3, 2007, entitled “NON-PERIPHERALS PROCESSING CONTROL MODULE HAVING IMPROVED HEAT DISSIPATING PROPERTIES,” which is a continuation application of U.S. patent application Ser. No. 10/691,473, filed Oct. 22, 2003, entitled “NON-PERIPHERALS PROCESSING CONTROL MODULE HAVING IMPROVED HEAT DISSIPATING PROPERTIES,” now issued as U.S. Pat. No. 7,256,991, which claims priority to U.S. Provisional Application Ser. No. 60/420,127, filed Oct. 22, 2002, entitled “NON-PERIPHERALS PROCESSING CONTROL UNIT HAVING IMPROVED HEAT DISSIPATING PROPERTIES,” and to U.S. Provisional Application Ser. No. 60/455,789, filed Mar. 19, 2003, entitled “SYSTEMS AND METHODS FOR PROVIDING A DURABLE AND DYNAMICALLY MODULAR PROCESSING UNIT,” which are all expressly incorporated herein by reference in their entireties.

U.S. patent application Ser. No. 13/154,325 filed Jun. 6, 2011, entitled “SYSTEMS AND METHODS FOR PROVIDING A UNIVERSAL COMPUTING SYSTEM” (Attorney Docket No. 11072.435) also claimed priority to the following provisional applications: Ser. No. 61/407,904 (Attorney Docket Number: 11072.268) titled “MODULAR VIRTUALIZATION IN COMPUTER SYSTEMS” filed Oct. 28, 2010, Ser. No. 61/352,349 (Attorney Docket Number: 11072.239) titled “SYSTEMS AND METHODS FOR OPTIMIZING MEMORY PERFORMANCE” filed Jun. 7, 2010, Ser. No. 61/352,351 (Attorney Docket Number: 11072.240) titled “SYSTEMS AND METHODS FOR PROVIDING MULTI-LINK DYNAMIC PCIE PARTITIONING” filed Jun. 7, 2010, Ser. No. 61/352,357 (Attorney Docket Number: 11072.241) titled “TRACKING APPARATUS” filed Jun. 7, 2010, Ser. No. 61/352,359 (Attorney Docket Number: 11072.242) titled “MINIATURIZED POWER SUPPLY” filed Jun. 7, 2010, Ser. No. 61/352,363 (Attorney Docket Number: 11072.243) titled “SYSTEMS AND METHODS FOR PROVIDING MULTI-LINK DYNAMIC VIDEO PARTITIONING” filed Jun. 7, 2010, Ser. No. 61/352,369 (Attorney Docket Number: 11072.244) titled “SYSTEMS AND METHODS FOR PROVIDING A PIN GRID ARRAY TO BALL GRID ARRAY ADAPTER” filed Jun. 7, 2010, Ser. No. 61/352,378 (Attorney Docket Number: 11072.245) titled “SYSTEMS AND METHODS FOR ACTIVATING MULTICOLOR LIGHT EMITTING DIODES” filed Jun. 7, 2010, Ser. No. 61/352,379 (Attorney Docket Number: 11072.246) titled “SYSTEMS AND METHODS FOR PROVIDING CONNECTIVITY” filed Jun. 7, 2010, Ser. No. 61/352,362 (Attorney Docket Number: 11072.247) titled “SYSTEMS AND METHODS FOR INTELLIGENT AND FLEXIBLE MANAGEMENT AND MONITORING OF COMPUTER SYSTEMS” filed Jun. 7, 2010, Ser. No. 61/352,368 (Attorney Docket Number: 11072.248) titled “MULTI-LINK DYNAMIC BUS PARTITIONING” filed Jun. 7, 2010, Ser. No. 61/352,372 (Attorney Docket Number: 11072.249) titled “MULTI-LINK DYNAMIC STORAGE PARTITIONING” filed Jun. 7, 2010, Ser. No. 61/352,384 (Attorney Docket Number: 11072.250) titled “LOAD BALANCING MODULAR COOLING SYSTEM” filed Jun. 7, 2010, Ser. No. 61/352,381 (Attorney Docket Number: 11072.251) titled “SYSTEMS AND METHODS FOR WIRELESSLY RECEIVING COMPUTER SYSTEM DIAGNOSTIC INFORMATION” filed Jun. 7, 2010, Ser. No. 61/352,358 (Attorney Docket Number: 11072.252) titled “SYSTEMS AND METHODS FOR PROVIDING A CUSTOMIZABLE COMPUTER PROCESSING UNIT” filed Jun. 7, 2010, Ser. No. 61/352,383 (Attorney Docket Number: 11072.253) titled “SYSTEMS AND METHODS FOR MOUNTING” filed Jun. 7, 2010, which are all expressly incorporated herein by reference in their entireties.

### BACKGROUND OF THE INVENTION

1. Field of the Invention

The present invention relates to mounting dynamically modular processing units. In particular, the present invention relates systems and methods for mounting a modular processing unit that is configured to be selectively used alone or with other processing units in an enterprise.

2. Background and Related Art

Technological advancements have occurred over the years with respect to computer related technologies. For example, computer systems once employed vacuum tubes. The tubes were replaced with transistors. Magnetic cores were used for memory. Thereafter, punch cards and magnetic tapes were commonly employed. Integrated circuits and operating systems were introduced. Today, microprocessor chips are currently used in computer systems.

The evolution of computer related technologies has included the development of various form factors in the computer industry. One such standard form factor was referred to as Advanced Technology (“AT”), which ran considerably faster than prior systems and included a new keyboard, an 80286 processor, a floppy drive that had a higher-capacity (1.2 MB) than prior systems and a 16-bit data bus.

Over time, improvements were made to the AT form factor that included a change in the orientation of the motherboard. The improvements allowed for a more efficient design of the motherboard by locating disk drive connectors closer to drive bays and the central processing unit closer to the power supply and cooling fan. The new location of the central processing unit allowed the expansion slots to all hold full-length add-in cards.

While the developments increased the processing ability, the techniques have only been marginally effective in their ability to upgrade components as the computer technology advances. In fact, the techniques have become increasingly less desirable as a delivery mechanism for computer technologies. Predictable failure patterns have been identified in terms of operating durability, manufacturing, shipping, and support. The systems generate heat, which requires internal cooling systems that are noisy. Moreover, current computer systems are prone to requiring repair.

Thus, while computer technologies currently exist that are configured for use in processing data, challenges still exist. Accordingly, it would be an improvement in the art to augment or even replace current techniques with other techniques.

### SUMMARY OF THE INVENTION

The present invention relates to mounting dynamically modular processing units. In particular, the present invention relates systems and methods for mounting a modular processing unit that is configured to be selectively used alone or with other processing units in an enterprise.

Implementation of the present invention takes place in association with a modular processing unit that is lightweight, compact, and is configured to be selectively used alone or with similar and/or other processing units in an enterprise. In some implementations, each modular processing unit includes a non-peripheral based encasement, a cooling process (e.g., thermodynamic convection cooling, forced air, and/or liquid cooling), an optimized circuit board configuration, optimized processing and memory ratios, and/or a dynamic back plane that provides increased flexibility and support to peripherals and applications.

In one implementation, a dynamically modular processing unit is a cube platform (e.g., approximately 4-inch cube platform or another size and/or configuration) that utilizes an advanced cooling process (e.g., a thermodynamic cooling model that eliminates any need for a cooling fan, a forced air cooling process and/or a liquid cooling process). The unit also includes one or more boards in a motherboard configuration, and optimized processing and memory ratios. The bus architecture of the unit enhances performance and increases both hardware and software stability. A highly flexible back plane provides support to peripherals and vertical applications. Other implementations of the present invention embrace the use of a durable and dynamically modular processing unit that is greater than or less than a 4-inch cube platform. Similarly, other implementations embrace the use of shapes other than a cube.

Implementation of the present invention provides a platform that may be employed in association with all types of computer enterprises. The platform allows for a plethora of modifications that may be made with minimal impact to the dynamically modular unit, thereby enhancing the usefulness of the platform across all type of applications.

In some implementations, a first dynamically modular processing unit is utilized as a base module and is communicatively connected to a second dynamically modular processing unit, which is utilized as a peripheral module to use processing resources of the base module using one or more input/output devices connected to the peripheral module, whereby the peripheral module facilitates a user's opening a session on the base module while using significantly less power for the peripheral module itself than any existing computer system.

Further implementations provide a system for distributing computing resources that includes a base module having certain processing resources. The system also includes a peripheral module communicatively connected to the base module and configured to utilize processing resources of the base module using one or more input/output devices connected to the peripheral module, wherein the peripheral module utilizes only enough computing resources to pass input/output signals between the input/output devices at the peripheral module and the base module.

Still further implementations provide a system for efficiently managing and distributing computing resources including a base module having certain processing resources and providing a first user with a graphical user interface providing access to a first session of an operating system of the base module. The system also includes a peripheral module communicatively connected to the base module and providing a second user with a graphical user interface providing access to a second session of the operating system of the base module without requiring that a separate instance of the operating system be loaded into memory of the base module.

Additional implementations of the present invention provide intelligent mounting brackets having a structure configured to be mounted to an underlying surface and to securely hold or retain a mounted item. In at least some implementations, the structure retains and/or contains a computer system configured to distribute processing resources from a remote computer system to one or more computer resources proximate to the mounting bracket.

Additional implementations of the present invention relate to mounting dynamically modular processing units (including base modules and/or peripheral modules) in a variety of different enterprises. In at least some implementations, the manner of mounting is determined by the particular enterprise needed and corresponding environment. In at least some implementations, shock mounting is included to provide for needed shock and vibe requirements. In some implementations, the mounting system includes a fixed mounting system for environments that need to be fixably secured. In other implementations, a selectively releasable connector is provided to allow for ease in mounting and removing the dynamically modular processing unit. In other implementations, a press-fit connector is provided to allow for ease in mounting and removing the dynamically modular processing unit.

While the methods and processes of the present invention have proven to be particularly useful in the area of personal and other computing enterprises, those skilled in the art will appreciate that the methods and processes of the present invention can be used in a variety of different applications and in a variety of different areas of manufacture to yield customizable enterprises, including enterprises for any industry utilizing control systems or smart-interface systems and/or enterprises that benefit from the implementation of such devices. Examples of such industries include, but are not limited to, automotive industries, avionic industries, hydraulic control industries, auto/video control industries, telecommunications industries, medical industries, special application industries, electronic consumer device industries, and other industries using a computer device. Accordingly, the systems and methods of the present invention provide massive computing power to markets, including markets that have traditionally been untapped by current computer techniques.

These and other features and advantages of the present invention will be set forth or will become more fully apparent in the description that follows. The features and advantages may be realized and obtained by means of the instruments and combinations provided herein. Furthermore, the features and advantages of the invention may be learned by the practice of the invention or will be obvious from the description, as set forth hereinafter.

### BRIEF DESCRIPTION OF THE DRAWINGS

In order to set forth the manner in which the above recited and other features and advantages of the present invention are obtained, a more particular description of the invention will be rendered by reference to specific embodiments thereof, which are illustrated in the appended drawings. Understanding that the drawings depict only typical embodiments of the present invention and are not, therefore, to be considered as limiting the scope of the invention, the present invention will be described and explained with additional specificity and detail through the use of the accompanying drawings in which:

FIG. 1 illustrates a block diagram that provides a representative modular processing unit in accordance with an embodiment of the present invention;

FIG. 2 illustrates a perspective view of a representative modular processing unit;

FIG. 3 illustrates another perspective view of the representative modular processing unit of FIG. 2;

FIG. 4 illustrates a perspective view of a representative encasement of a modular processing unit, and more particularly a representative support chassis of a modular processing unit;

FIG. 5 illustrates an exploded view of main support chassis, with inserts and dynamic back plane in accordance with an embodiment of the present invention;

FIG. 6 illustrates a representative end plate;

FIG. 7 illustrates a representative end cap;

FIG. 8 illustrates a representative modular processing unit with dynamic back plane;

FIG. 9 illustrates a representative modular processing unit with the end plates removed;

FIG. 10 illustrates a modular processing unit operably connecting to an external object of any type;

FIG. 11 illustrates a representative computing enterprise;

FIG. 12 illustrates a representative enterprise having a modular processing unit coupled to a monitor;

FIG. 13 illustrates another representative enterprise having a modular processing unit coupled to a monitor;

FIG. 14 illustrates an exploded view of a representative modular processing unit, shown as a representative peripheral module;

FIG. 15 illustrates an enterprise having two modular processing units interoperably connected, namely a representative base module and a representative peripheral module;

FIG. 16 illustrates an end view of a representative peripheral module;

FIG. 17 illustrates a perspective view of a representative peripheral module;

FIG. 18 illustrates a perspective view of a representative peripheral module;

FIG. 19 illustrates an end view of an outer structural shell of an alternative representative peripheral module;

FIG. 20 illustrates a perspective view of a representative mounting plate;

FIG. 21 illustrates a representative mounting system;

FIG. 22 illustrates another representative mounting bracket;

FIG. 23 illustrates a representative manner of mounting a modular processing unit;

FIG. 24 illustrates an assembled view of the representative manner of mounting a modular processing unit of FIG. 23;

FIG. 25 illustrates another representative manner of mounting a modular processing unit;

FIG. 26 illustrates an assembled view of the representative manner of mounting a modular processing unit of FIG. 25;

FIG. 27 illustrates another representative manner of mounting a modular processing unit;

FIG. 28 illustrates an assembled view of the representative manner of mounting a modular processing unit of FIG. 27;

FIG. 29 illustrates a top view of the representative manner of mounting a modular processing unit of FIG. 27;

FIG. 30 illustrates a perspective view of the representative manner of mounting a modular processing unit of FIG. 27;

FIG. 31 illustrates a perspective view of another representative mounting bracket;

FIG. 32 illustrates a representative manner of mounting a modular processing unit;

FIG. 33 illustrates an assembled view of the representative manner of mounting a modular processing unit of FIG. 32;

FIG. 34 illustrates a representative manner of mounting modular processing units in a rack or cabinet;

FIG. 35 illustrates another representative manner of mounting modular processing units in a rack or cabinet;

FIG. 36 illustrates a representative DIN rail mounting system;

FIG. 37 illustrates another view of a representative DIN rail mounting system;

FIG. 38 illustrates another view of a representative DIN rail mounting system;

FIG. 39 illustrates another representative mounting system;

FIG. 40 illustrates a representative container in accordance with the representative mounting system of FIG. 39;

FIG. 41 illustrates the representative container of FIG. 40 with a modular processing unit mounted therein;

FIG. 42 illustrates mounting the representative modular processing unit into the representative container of FIG. 40;

FIGS. 43-44 further illustrate mounting the representative modular processing unit into the representative container of FIG. 40; and

FIG. 45 illustrates another view of the representative mounting system of FIG. 39.

### DETAILED DESCRIPTION OF THE INVENTION

The present invention relates to mounting dynamically modular processing units. In particular, the present invention relates systems and methods for mounting a modular processing unit that is configured to be selectively used alone or with other processing units (base modules and/or peripheral modules) in an enterprise.

In at least some embodiments, the manner of mounting is determined by the particular enterprise needed and corresponding environment. In at least some embodiments, shock mounting is included to provide for needed shock and vibe requirements. In some embodiments, the mounting system includes a fixed mounting system for environments that need to be secured. In other embodiments, a selectively releasable connector is provided to allow for ease in mounting and removing the dynamically modular processing unit. In other embodiments, a press-fit connector is provided to allow for ease in mounting and removing the dynamically modular processing unit.

The following portion of the description is broken into several headings for purposes of increasing understanding of the description, and is not intended to be limiting in any way.

### Representative Operating Environments

The present invention relates to systems and methods for mounting a dynamically modular processing unit. In particular, embodiments of the present invention take place in association with a modular processing unit that is lightweight, compact, and is configured to be selectively used alone or oriented with one or more additional processing units in an enterprise. In some embodiments, a modular processing unit includes a non-peripheral based encasement, a cooling process (e.g., thermodynamic convection cooling, forced air, and/or liquid cooling), an optimized layered printed circuit board configuration, optimized processing and memory ratios, and a dynamic back plane that provides increased flexibility and support to peripherals and applications.

Embodiments of the present invention embrace a platform that may be employed in association with all types of computer and/or electrical enterprises. The platform allows for a plethora of modifications that may be made with minimal impact to the dynamic modular unit, thereby enhancing the usefulness of the platform across all types of applications. Moreover, as indicated above, the modular processing unit may function alone or may be associated with one or more other modular processing units in a customizable enterprise to provide enhanced processing capabilities.

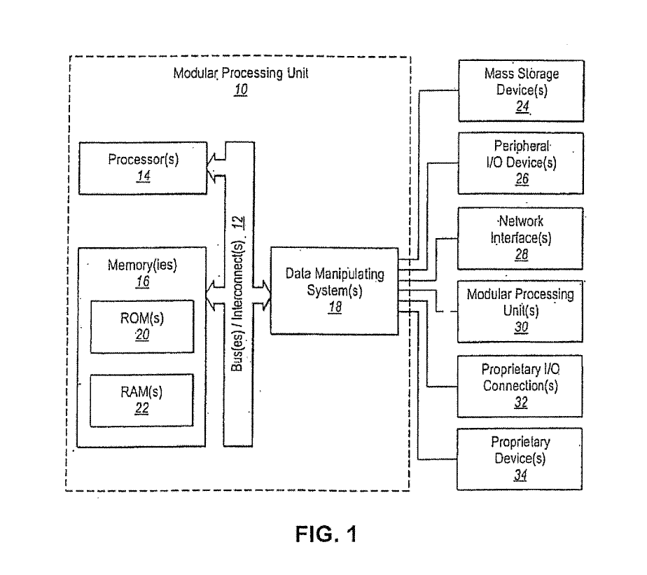

FIG. 1 and the corresponding discussion are intended to provide a general description of a suitable operating environment in accordance with embodiments of the present invention. As will be further discussed below, embodiments of the present invention embrace the use of one or more dynamically modular processing units in a variety of customizable enterprise configurations, including in a networked or combination configuration, as will be discussed below.

Embodiments of the present invention embrace one or more computer readable media, wherein each medium may be configured to include or includes thereon data or computer executable instructions for manipulating data. The computer executable instructions include data structures, objects, programs, routines, or other program modules that may be accessed by one or more processors, such as one associated with a general-purpose modular processing unit capable of performing various different functions or one associated with a special-purpose modular processing unit capable of performing a limited number of functions.

Computer executable instructions cause the one or more processors of the enterprise to perform a particular function or group of functions and are examples of program code means for implementing steps for methods of processing. Furthermore, a particular sequence of the executable instructions provides an example of corresponding acts that may be used to implement such steps.

Examples of computer readable media include random-access memory (“RAM”), read-only memory (“ROM”), programmable read-only memory (“PROM”), erasable programmable read-only memory (“EPROM”), electrically erasable programmable read-only memory (“EEPROM”), compact disk read-only memory (“CD-ROM”), any solid state storage device (e.g., flash memory, smart media, etc.), or any other device or component that is capable of providing data or executable instructions that may be accessed by a processing unit.

With reference to FIG. 1, a representative enterprise includes modular processing unit 10, which may be used as a general-purpose or special-purpose processing unit. For example, modular processing unit 10 may be employed alone or with one or more other modular processing units as a personal computer, a notebook computer, a personal digital assistant (“PDA”) or other hand-held device, a workstation, a minicomputer, a mainframe, a supercomputer, a multi-processor system, a network computer, a processor-based consumer device, a smart appliance or device, a control system, or other computer system. Using multiple processing units in the same enterprise provides increased processing capabilities. For example, each processing unit of an enterprise can be dedicated to a particular task or can jointly participate in distributed processing.

In FIG. 1, modular processing unit 10 includes one or more buses and/or interconnect(s) 12, which may be configured to connect various components thereof and enables data to be exchanged between two or more components. Bus(es)/interconnect(s) 12 may include one of a variety of bus structures including a memory bus, a peripheral bus, or a local bus that uses any of a variety of bus architectures. Typical components connected by bus(es)/interconnect(s) 12 include one or more processors 14 and one or more memories 16. Other components may be selectively connected to bus(es)/interconnect(s) 12 through the use of logic, one or more systems, one or more subsystems and/or one or more I/O interfaces, hereafter referred to as “data manipulating system(s) 18.” Moreover, other components may be externally connected to bus(es)/interconnect(s) 12 through the use of logic, one or more systems, one or more subsystems and/or one or more I/O interfaces, and/or may function as logic, one or more systems, one or more subsystems and/or one or more I/O interfaces, such as modular processing unit(s) 30 and/or proprietary device(s) 34. Examples of I/O interfaces include one or more mass storage device interfaces, one or more input interfaces, one or more output interfaces, and the like. Accordingly, embodiments of the present invention embrace the ability to use one or more I/O interfaces and/or the ability to change the usability of a product based on the logic or other data manipulating system employed.

The logic may be tied to an interface, part of a system, subsystem and/or used to perform a specific task. Accordingly, the logic or other data manipulating system may allow, for example, for IEEE1394 (firewire), wherein the logic or other data manipulating system is an I/O interface. Alternatively or additionally, logic or another data manipulating system may be used that allows a modular processing unit to be tied into another external system or subsystem. For example, an external system or subsystem that may or may not include a special I/O connection. Alternatively or additionally, logic or other data manipulating system may be used wherein no external I/O is associated with the logic. Embodiments of the present invention also embrace the use of specialty logic, such as for ECUs for vehicles, hydraulic control systems, etc. and/or logic that informs a processor how to control a specific piece of hardware. Moreover, those skilled in the art will appreciate that embodiments of the present invention embrace a plethora of different systems and/or configurations that utilize logic, systems, subsystems and/or I/O interfaces.

As provided above, embodiments of the present invention embrace the ability to use one or more I/O interfaces and/or the ability to change the usability of a product based on the logic or other data manipulating system employed. For example, where a modular processing unit is part of a personal computing system that includes one or more I/O interfaces and logic designed for use as a desktop computer, the logic or other data manipulating system may be changed to include flash memory or logic to perform audio encoding for a music station that wants to take analog audio via two standard RCAs and broadcast them to an IP address. Accordingly, the modular processing unit may be part of a system that is used as an appliance rather than a computer system due to a modification made to the data manipulating system(s) (e.g., logic, system, subsystem, I/O interface(s), etc.) on the back plane of the modular processing unit. Thus, a modification of the data manipulating system(s) on the back plane can change the application of the modular processing unit. Accordingly, embodiments of the present invention embrace very adaptable modular processing units.

As provided above, processing unit 10 includes one or more processors 14, such as a central processor and optionally one or more other processors designed to perform a particular function or task. It is typically processor 14 that executes the instructions provided on computer readable media, such as on memory(ies) 16, a magnetic hard disk, a removable magnetic disk, a magnetic cassette, an optical disk, solid state memory, flash, or from a communication connection, which may also be viewed as a computer readable medium.

Memory(ies) 16 includes one or more computer readable media that may be configured to include or includes thereon data or instructions for manipulating data, and may be accessed by processor(s) 14 through bus(es)/interconnect(s) 12. Memory(ies) 16 may include, for example, ROM(s) 20, used to permanently store information, and/or RAM(s) 22, used to temporarily store information. ROM(s) 20 may include a basic input/output system (“BIOS”) having one or more routines that are used to establish communication, such as during start-up of modular processing unit 10. During operation, RAM(s) 22 may include one or more program modules, such as one or more operating systems, application programs, and/or program data.

As illustrated, at least some embodiments of the present invention embrace a non-peripheral encasement, which provides a more robust processing unit that enables use of the unit in a variety of different applications. In FIG. 1, one or more mass storage device interfaces (illustrated as data manipulating system(s) 18) may be used to connect one or more mass storage devices 24 to bus(es)/interconnect(s) 12. The mass storage devices 24 are peripheral to modular processing unit 10 and allow modular processing unit 10 to retain large amounts of data. Examples of mass storage devices include hard disk drives, magnetic disk drives, tape drives, flash drive, optical disk drives, and other storage devices.

A mass storage device 24 may read from and/or write to a magnetic hard disk, a removable magnetic disk, a magnetic cassette, an optical disk, or another computer readable medium. Mass storage devices 24 and their corresponding computer readable media provide nonvolatile storage of data and/or executable instructions that may include one or more program modules, such as an operating system, one or more application programs, other program modules, or program data. Such executable instructions are examples of program code means for implementing steps for methods disclosed herein.

Data manipulating system(s) 18 may be employed to enable data and/or instructions to be exchanged with modular processing unit 10 through one or more corresponding peripheral I/O devices 26. Examples of peripheral I/O devices 26 include input devices such as a keyboard and/or alternate input devices, such as a mouse, trackball, light pen, stylus, or other pointing device, a microphone, a joystick, a game pad, a satellite dish, a scanner, a camcorder, a digital camera, a sensor, and the like, and/or output devices such as a monitor or display screen, a speaker, a printer, a control system, and the like. Similarly, examples of data manipulating system(s) 18 coupled with specialized logic that may be used to connect the peripheral I/O devices 26 to bus(es)/interconnect(s) 12 include a serial port, a parallel port, a game port, a universal serial bus (“USB”), a firewire (IEEE 1394), a wireless receiver, a video adapter, an audio adapter, a parallel port, a wireless transmitter, any parallel or serialized I/O peripherals or another interface.

Data manipulating system(s) 18 enable an exchange of information across one or more network interfaces 28. Examples of network interfaces 28 include a connection that enables information to be exchanged between processing units, a network adapter for connection to a local area network (“LAN”) or a modem, a wireless link, or another adapter for connection to a wide area network (“WAN”), such as the Internet. Network interface 28 may be incorporated with or peripheral to modular processing unit 10, and may be associated with a LAN, a wireless network, a WAN and/or any connection between processing units.

Data manipulating system(s) 18 enable modular processing unit 10 to exchange information with one or more other local or remote modular processing units 30 or computer devices. A connection between modular processing unit 10 and modular processing unit 30 may include hardwired and/or wireless links. Accordingly, embodiments of the present invention embrace direct bus-to-bus connections. This enables the creation of a large bus system. It also eliminates hacking as currently known due to direct bus-to-bus connections of an enterprise. Furthermore, data manipulating system(s) 18 enable modular processing unit 10 to exchange information with one or more proprietary I/O connections 32 and/or one or more proprietary devices 34.

Program modules or portions thereof that are accessible to the processing unit may be stored in a remote memory storage device. Furthermore, in a networked system or combined configuration, modular processing unit 10 may participate in a distributed computing environment where functions or tasks are performed by a plurality of processing units. Alternatively, each processing unit of a combined configuration/enterprise may be dedicated to a particular task. Thus, for example, one processing unit of an enterprise may be dedicated to video data, thereby replacing a traditional video card, and provides increased processing capabilities for performing such tasks over traditional techniques.

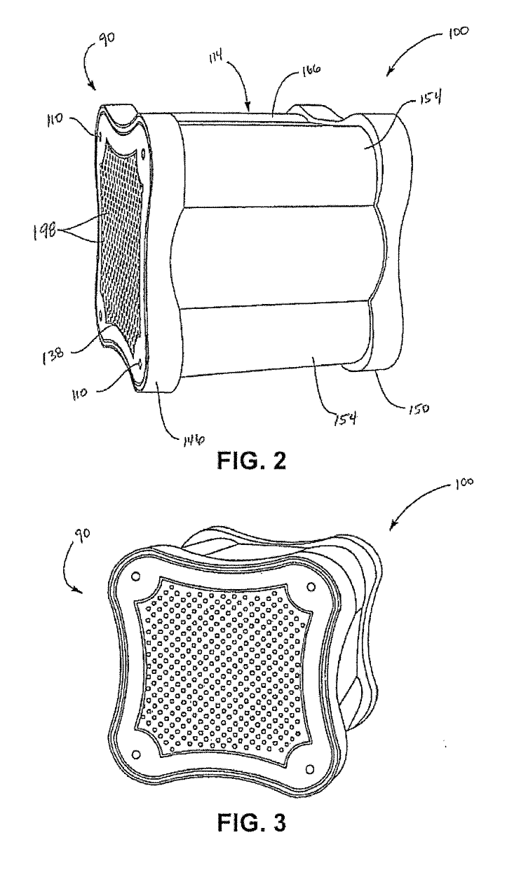

While those skilled in the art will appreciate that embodiments of the present invention may comprise a variety of configurations, reference is made to FIGS. 2-3, which illustrate a representative embodiment of a durable and dynamically modular processing unit 90. Modular processing unit 90 comprises a proprietary encasement module 100 (hereinafter referred to as “encasement module 100”), as well as a proprietary printed circuit board design. Modular processing unit 90, through the specific and calculated design of encasement module 100, provides unparalleled computer processing advantages and features not found in prior art processing units or computers. Indeed, the present invention processing unit as described and claimed herein presents a complete conceptual shift, or paradigm shift, from conventional computers or processing units. This paradigm shift will become evident from the subject matter of the disclosure below, which subject matter is embodied in the appended claims.

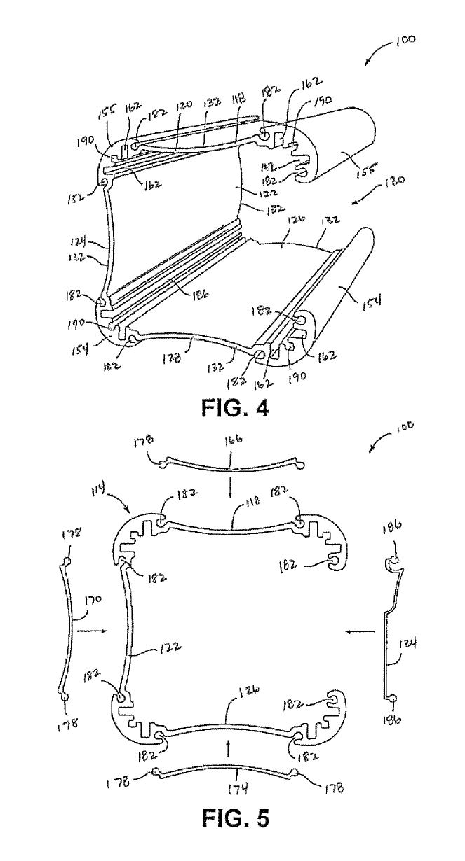

FIGS. 2-3 show a representative modular processing unit, identified as modular processing unit 90, in its fully assembled state with many of the primary components generally illustrated. As stated, modular processing unit 90 comprises encasement module 100, which itself has a very specific and unique support structure and geometric configuration or design that is more fully described in FIG. 4. In one preferred embodiment, encasement module 100 comprises a main support chassis 114; first insert 166; second insert 170; third insert 174 (not shown); dynamic backplane 134 (not shown); first end plate 138; second end plate 142 (not shown); first end cap 146; and second end cap 150 to provide an enclosed housing or encasement for one or more processing and other computer components, such as printed circuit boards, processing chips, and circuitry.

FIGS. 4-5 illustrate a representative embodiment of main support chassis 114 and some of the component parts of encasement module 100 as designed to attach or couple to main support chassis 114. Preferably, these component parts are removably coupled to chassis 114, as shown, in order to enable some of the unique features and functions of modular processing unit 90 as described and set forth herein. Main support chassis 114 serves as the primary support structure for encasement module 100 and modular processing unit 90. Its small size and proprietary design provide advantages and benefits not found in prior art designs. Essentially, main support chassis 114 provides structural support for the component parts of modular processing unit 90, including any additional physical attachments, processing and other circuit board components, as well as enabling modular processing unit 90 to be adaptable to any type of environment, such as incorporation into any known structure or system, or to be used in clustered and multi-plex environments.

Specifically, as shown in the figures, modular processing unit 90, and particularly encasement module 100, is essentially comprised of a cube-shaped design, wherein first, second, and third wall supports 118, 122, and 126 of main support chassis 114, along with dynamic backplane 134 when attached, comprise the four sides of encasement module 100, with a union module 154 positioned at each corner of encasement module 100.

Junction center 155 functions to integrally join first, second, and third wall supports 118, 122, and 126, as well as to provide a base to which the end plates discussed below may be attached. End plates are coupled to main support chassis 114 using attachment means as inserted into attachment receipt 90, which is shown in FIG. 4 as an aperture, which may be threaded or not depending upon the particular type of attachment means used. Junction center 155 further provide the primary support and the junction center for the proprietary printed circuit board design existing within modular processing unit 90 as discussed below. As shown in FIG. 4, printed circuit boards are capable of being inserted into and secured within one or more channeled board receivers 162. The particular design shown in the figures and described herein is merely a representative example of securing or engaging printed circuit boards within modular processing unit 90. Other designs, assemblies, or devices are contemplated and may be used as recognized by one ordinarily skilled in the art. For instance, means for securing processing components may include screws, rivets, interference fits, and other connectors.

Main support chassis 114 further comprises a plurality of channels or slide receivers 182 designed to receive a corresponding insert located on one or more insert members, a dynamic back plane, a chassis, a mounting bracket used to couple two or more processing units together, or to allow the processing unit to be implemented into another structure. Slide receivers 182 may also be used to accept or receive suitable elements of a structure or a structure or device itself, wherein the processing unit, and specifically the encasement module, serves as a load bearing member. The ability of modular processing unit 90 to function as a load bearing member is derived from its unique chassis design. For example, modular processing unit 90 may be used to bridge two structures together and to contribute to the overall structural support and stability of the structure. In addition, modular processing unit 90 may bear a load attached directly to main support chassis 114. For example, a computer screen or monitor may be physically supported and process controlled by modular processing unit 90. As further examples, modular processing unit 90 may be used to physically support and process control various home fixtures, such a lighting fixture, or a breaker box, etc. Moreover, if needed, an additional heat sink assembly may be coupled to modular processing unit 90 in a similar manner. Many other possible load bearing situations or environments are possible and contemplated herein. Thus, those specifically recited herein are only meant to be illustrative and not limiting in any way. Slide receivers 182 are shown as substantially cylindrical channels running the length of the junction center 155 of main support chassis 114. Slide receivers 182 comprise merely one manner of coupling external components to main support chassis 114. Other designs or assemblies are contemplated and may be used to carry out the intended function of providing means for attaching various component parts such as those described above as recognized by one ordinarily skilled in the art.

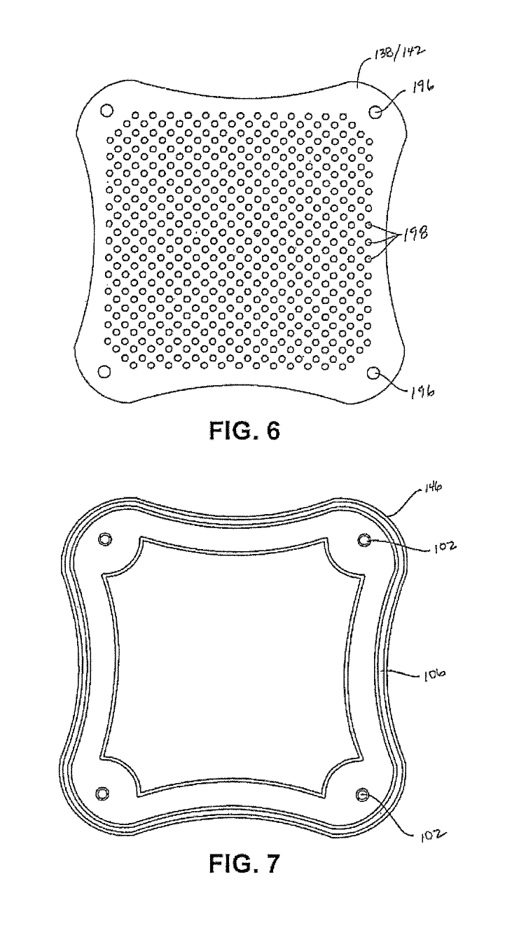

FIGS. 4-5 further illustrate the concave nature of main support chassis 114, and particularly first, second, and third wall supports 118, 122, and 126. First, second, and third insert members 166, 170, and 174 comprise corresponding concave designs. Each of these component parts further comprise a specifically calculated radius of curvature, such that first wall support 118 comprises a radius of curvature 120 to correspond to a mating radius of curvature designed into first insert 166. Likewise, second wall support 122 comprises a radius of curvature 124 to correspond to a mating radius of curvature designed into second insert 170, and third wall support 126 comprises a radius of curvature 128 to correspond to a mating radius of curvature designed into third insert 174. End plates 138 and 142, as well as end caps 146 and 150, as illustrated in FIGS. 6-7, each comprise similar design profiles to match the concave design profile of main support chassis 114. In the embodiment shown in the figures, the wall supports and the insert members each comprise a radius of curvature. The concaved design and the calculated radius' of curvature each contribute to overall structural rigidity and strength of main support chassis 114, as well as contributing to the thermodynamic heat dissipating properties of modular processing unit 90. For example in a natural convection cooling system, described in greater detail below, the concaved design facilitates the distribution of heated air to the outer, and primarily upper, corners of encasement module 100, thus allowing heat or heated air to be dispersed away from the top and center of the interior portion of modular processing unit 90 and towards the upper right and left corners, where it may then escape thru ventilation ports 198 or where it may be further conducted through the top of encasement module 100. Other embodiments are contemplated where the radius of curvature of these elements may differ from one another to provide the most optimal design of encasement module 100 as needed.

In a preferred embodiment, main support chassis 114 comprises a full metal chassis that is structured and designed to provide an extremely strong support structure for modular processing unit 90 and the components contained therein. Under normal circumstances, and even extreme circumstances, main support chassis 114 is capable of withstanding very large applied and impact forces originating from various external sources, such as those that would normally cause disfiguration or denting to prior related computer encasements, or limit their ability to be used in other or extreme environments. Essentially, main support chassis 114 is the main contributor to providing a virtually indestructible computer encasement for modular processing unit 90. This unique feature in a computer encasement is in direct relation to the particular design of the components used to construct encasement module 100, including their geometric design, the way they are fit together, their material composition, and other factors, such as material thickness. Specifically, encasement module 100 is preferably built entirely out of radiuses, wherein almost every feature and element present comprises a radius. This principle of radiuses is utilized to function so that any load applied to modular processing unit 90 is transferred to the outer edges of modular processing unit 90. Therefore, if a load or pressure is applied to the top of encasement module 100, that load would be transferred along the sides, into the top and base, and eventually into the corners of encasement module 100. Essentially, any load applied is transferred to the corners of modular processing unit 90, where the greatest strength is concentrated.

Modular processing unit 90 and its components, namely encasement module 100, main support chassis 114, inserts 166, 170, and 174, dynamic backplane 134, and end plates 138 and 142, are each preferably manufactured of metal using an extrusion process. In one embodiment, main support chassis 114, first, second, and third inserts 166, 170, and 174, dynamic backplane 134, and first and second end plates 138 and 142 are made of high-grade aluminum to provide strong, yet light-weight characteristics to encasement module 100. In addition, using a metal casing provides good heat conducting properties. Although preferably constructed of aluminum or various grades of aluminum and/or aluminum composites, it is contemplated that various other materials, such as titanium, copper, magnesium, the newly achieved hybrid metal alloys, steel, and other metals and metal alloys, as well as plastics, graphites, composites, nylon, or a combination of these depending upon the particular needs and/or desires of the user, may be used to construct the main components of encasement module 100. In essence, the intended environment for or use of the processing unit will largely dictate the particular material composition of its constructed components. As stated, an important feature of the present invention is the ability of the processing unit to adapt and be used for several uses and within several different and/or extreme environments. As such, the specific design of the processing unit relies upon a concerted effort to utilize the proper material. Stated differently, the processing unit of the present invention contemplates using and comprises a pre-determined and specifically identified material composition that would best serve its needs in light of its intended use. For example, in a liquid cooled model or design, a more dense metal, such as titanium, may be used to provide greater insulative properties to the processing unit.

Given its preferred aluminum composition, encasement module 100 is very strong, light-weight, and easy to move around, thus providing significant benefits extending to both the end user and the manufacturer. For example, from an end user standpoint, modular processing unit 90 may be adapted for use within various environments in which prior related computers could not be found. In addition, an end user may essentially hide, mask, or camouflage modular processing unit 90 to provide a more clean looking, less-cluttered room, or to provide a more aesthetically appealing workstation.

From a manufacturing standpoint, encasement module 100 and modular processing unit 90 are capable of being manufactured using one or more automated assembly processes, such as an automated aluminum extrusion process-coupled with an automated robotics process for installing or assembling each of the component parts as identified above. Equally advantageous is the ability for encasement module 100 to be quickly mass-produced as a result of its applicability to an extrusion and robotics assembly process. Of course, modular processing unit 90 may also be manufactured using other known methods, such as die casting and injection molding, hand assembly depending upon the particular characteristics desired and the particular intended use of the processing unit.

In addition, since encasement module 100 is small in size and relatively light-weight, shipping costs, as well as manufacturing costs, are also greatly reduced.

With reference to FIG. 5, shown are the main components of encasement module 100, namely main support chassis 114 and the several inserts that are designed to removably attach or couple to the sides of main support chassis 114. FIG. 5 also illustrates dynamic backplane 134 as it is designed to removably attach or couple to the rear portion of main support chassis 114.

Specifically, first insert 166 attaches to first wall support 118. Second insert 170 attaches to second wall support 122. Third insert 174 attaches to third wall support 126. Moreover, each of first, second, and third inserts 166, 170, and 174, and first, second, and third wall supports 118, 122, and 126 comprise substantially the same radius of curvature so that they may mate or fit together in a nesting or matching relationship.

Each of first, second and third inserts 166, 170, and 174 comprise means for coupling main support chassis 114. In one exemplary embodiment, as shown in FIG. 5, each insert comprises two insert engagement members 178 located at opposing ends of the insert. Engagement members 178 are designed to fit within a means for engaging or coupling various external devices, systems, objects, etc. (hereinafter an external object) formed within main support chassis 114. In the exemplary embodiment shown, means for engaging an external object comprises a plurality of slide receivers 182 positioned along main support chassis 114 as shown and identified above in FIG. 4. Other means are also contemplated, such as utilizing various attachments ranging from snaps, screws, rivets, interlocking systems, and any others commonly known in the art.

Dynamic backplane 134 is also designed for or is capable of releasably coupling main support chassis 114. Dynamic backplane 134 comprises means for engaging main support chassis 114. In the exemplary embodiment shown, means for engaging is comprised of two engagement members 186 positioned at opposing ends of dynamic backplane 134. Engagement members 186 fit within slide receivers 182 at their respective locations along the rear portion of main support chassis 114 (shown as space 130) to removably attach dynamic backplane 134 to main support chassis 114, much the same way inserts 166, 170, and 174 attach to main support chassis 114 at their respective locations. These particular features are intended as one of several possible configurations, designs, or assemblies. Therefore, it is intended that one skilled in the art will recognize other means available for attaching dynamic backplane 134 to main support chassis 114 other than those specifically shown in the figures and described herein.

Means for engaging an external object, and particularly slide receiver 182, is capable of releasably coupling various types of external objects (as will be more fully described below), such as inserts 166, 170, and 174, dynamic backplane 134, mounting brackets, another processing unit, or any other needed device, structure, or assembly. As illustrated in FIG. 5, slide receivers 182 engage corresponding engagement members 178 in a releasable manner so as to allow each insert to slide in and out as needed. As stated, other means for coupling main support chassis 114 and means for engaging an external object are contemplated herein, and will be apparent to one skilled in the art.

By allowing each insert and dynamic backplane 134 to be removably or releasably coupled to main support chassis 114, several significant advantages to modular processing unit 90, over prior related computer encasements, are achieved. For example, and not intended to be limiting in any way, first, second, and third inserts 166, 170, and 174 may be removed, replaced, or interchanged for aesthetic purposes. These insert members may possess different colors and/or textures, thus allowing modular processing unit 90 to be customized to fit a particular taste or to be more adaptable to a given environment or setting. Moreover, greater versatility is achieved by allowing each end user to specify the look and overall feel of their particular unit. Removable or interchangeable insert members also provide the ability to brand (e.g., with logos and trademarks) modular processing unit 90 for any company entity or individual using the unit. Since they are external to main support chassis 114, the insert members will be able to take on any form or branding as needed.

Aside from aesthetics, other advantages are also recognized. On a higher level of versatility, means for engaging an external object provides modular processing unit 90 with the ability to be robust and customizable to create a smart object. For instance, processing unit may be docked in a mobile setting or in a proprietary docking station where it may serve as the control unit for any conceivable object, such as boats, cars, planes, and other items or devices that were heretofore unable to comprise a processing unit, or where it was difficult or impractical to do so.

With reference to FIG. 6, shown is an illustration of one of first end plate 138 or second end plate 142 that couple to first and second end portions 140 and 144 of primary chassis 114, respectively, and function to provide means for allowing air to flow or pass in and out of the interior of modular processing unit 90. First and second end plates 138 and 142 function with first and second end caps 146 and 150 (shown in FIG. 7), respectively, to provide a protective and functional covering to encasement module 100. Some embodiments do not include end caps. First and second end plates 138 and 142 attach to main support chassis 114, using attachment means 110 (as shown in FIG. 2). Attachment means 110 typically comprises various types of screws, rivets, and other fasteners as commonly known in the art, but may also comprise other systems or devices for attaching first and second end plates 138 and 142, along with first and second end caps 146 and 150, to main support chassis 114, as commonly known in the art. In a representative embodiment, attachment means 110 comprise a screw capable of fitting within the respective attachment receivers 190 located in union module 154 at the four corners of main support chassis 114 (attachment receivers 190 and union module 154 are illustrated in FIG. 4).

Structurally, first and second end plates 138 and 142 comprise a geometric shape and design to match that of end portions 140 and 144 of main support chassis 114. Specifically, as shown in FIG. 6, the perimeter profile of first and second end plates 138 and 142 comprises a series of concave edges, each having a radius of curvature to match those of the respective wall supports and dynamic back plane. Essentially, end plates 138 and 142 serve to close off the ends of encasement module 100 by conforming to the shape of encasement module 100.

One of the primary functions of first and second end plates 138 and 142 is to provide means for facilitating or allowing the influx of air into and efflux of air out of encasement module 100. In an exemplary embodiment as shown in FIG. 6, such means comprises a plurality of apertures or ventilation ports 198 intermittently spaced along the surface or face of and extending through end plates 138 and 142. As explained in the thermodynamics section below, in one embodiment, modular processing unit 90 utilizes natural convection to cool the processing components contained therein. By equipping end plates 138 and 142 with ventilation ports 198 ambient air is allowed to enter into the interior of modular processing unit 90, while the heated air, as generated from the processors and other components located within the interior of modular processing unit 90, is allowed to escape or flow from the interior to the outside environment. By natural physics, heated air rises and is forced out of encasement module 100 as cooler air is drawn into encasement module 100. This influx and efflux of ambient and heated air, respectively, allows modular processing unit 90 to utilize a natural convection cooling system to cool the processors and other internal components functioning or operating within modular processing unit 90. Ventilation ports 198 are preferably numerous, and span a majority of the surface area of end plates 138 and 142, and particularly the outer perimeter regions, thus enabling increased and efficient cooling of all internal components in an air-cooled model. Ventilation ports 198 are machined to exact specifications to optimize airflow and to constrict partial flow into encasement module 100. By constricting some flow, dust and other sediments or particles are prohibited from entering the interior of encasement module 100 where they can cause damage to and decreased performance of modular processing unit 90. Indeed, ventilation ports 198 are sized to only allow air particles to flow therethrough.

Because encasement module 100 is preferably made of metal, the entire structure, or a portion of the structure, can be positively or negatively charged to prohibit dust and other particles or debris from being attracted to the encasement. Such an electrostatic charge also prevents the possibility of a static charge jumping across dust and other elements and damaging the main board. Providing an electrostatic charge is similar to ion filtering, only opposite. By negatively charging encasement module 100, all positively charged ions (i.e. dust, dirt, etc.) are repelled.

FIG. 7 illustrates first end cap 146 and second end cap 150, which are designed to fit over first and second end plates 138 and 142, respectively, as well as over a portion of each end portion 140 and 144 of main support chassis 114. These end caps are preferably made of some type of impact absorbing plastic or rubber, thus serving to provide a barrier of protection to modular processing unit 90, as well as to add to its overall look and feel. Some embodiments do not include end caps.

In one embodiment, modular processing unit 90 comprises a rather small footprint or size relative to or as compared with conventional computer encasements. For example, in an exemplary embodiment, its geometric dimensions are approximately 4 inches in length, 4 inches in width, and 4 inches in height, which are much smaller than prior related conventional processing units, such as desktop computers or even most portable computers or laptops. In addition to its reduced dimensional characteristics, modular processing unit 90 comprises rather unique geometrical characteristics as well. FIGS. 2-3 illustrate this unique shape or geometry, most of which has been discussed above. These dimensional and geometrical characteristics are proprietary in form and each contribute to the specific, unique functional aspects and performance of modular processing unit 90. They also provide or lend themselves to significant features and advantages not found in prior related processing units. Stated differently, the proprietary design of modular processing unit 90 as described and shown herein allows it to perform in ways and to operate in environments that are otherwise impossible for prior related conventional computer encasements and processing units.

It is important to describe that modular processing unit 90 can take on any size and/or geometric shape. Although in the preferred embodiment modular processing unit 90 is substantially cube-shaped having a 4×4×4 size, other sizes and shapes are intended to be within the scope of the present invention. Specifically, as recited herein, the processing unit may be adapted for use in various structures or super structures, such as any conceivable by one ordinarily skilled in the art. In this sense, modular processing unit 90 must be able to comprise a suitable size and structure to be able to take on the physical attributes of its intended environment. For example, if processing unit is to be used within a thin hand-held device, it will be constructed having a thin profile physical design, thus deviating away from the cube-like shape of the preferred embodiment. As such, the various computer and processing components used within modular processing unit 90 are also capable of associated sizes and shapes and designs.

As described above, the present invention modular processing unit 90 was designed to have certain mainstream components exterior to encasement module 100 for multiple reasons. First, because of its small size, yet powerful processing capabilities, modular processing unit 90 may be implemented into various devices, systems, vehicles, or assemblies to enhance these as needed. Common peripheral devices, such as special displays, keyboards, etc., can be used in the traditional computer workstation, but modular processing unit 90 can also be without peripherals and customized to be the control unit for many items, systems, etc. In other words, modular processing unit 90 may be used to introduce “smart” technology into any type of conceivable item of manufacture (external object), such that the external object may perform one or more smart functions. A “smart function” may be defined herein as any type of computer executed function capable of being carried out by the external object as a result of the external object being operably connected and/or physically coupled to a computing system, namely processing unit.

Second, regarding cooling issues, most of the heat generated within the interior of a computer comes from two places—the computer processor and the hard drive. By removing the hard drive from the encasement module 100 and putting it within its own encasement exterior to modular processing unit 90, better and more efficient cooling is achieved. By improving the cooling properties of the system, the lifespan or longevity of the processor itself is increased, thus increasing the lifespan and longevity of the entire computer processing system.

Third, modular processing unit 90 preferably comprises an isolated power supply. By isolating the power supply from other peripherals more of the supplied voltage can be used just for processing versus using the same voltage to power the processor in addition to one or more peripheral components, such as a hard drive and/or a CD-ROM, existing within the system. In a workstation model, the peripheral components will exist without modular processing unit 90 and will be preferably powered by the monitor power supply.

Fourth, preferably no lights or other indicators are employed to signify that modular processing unit 90 is on or off or if there is any disk activity. Activity and power lights still may be used, but they are preferably located on the monitor or other peripheral housing device. This type of design is preferred as it is intended that the system be used in many applications where lights would not be seen or where they would be useless, or in applications where they would be destructive, such as dark rooms and other photosensitive environments. Obviously however, exterior lighting, such as that found on conventional computer systems to show power on or disk use, etc., may be implemented or incorporated into the actual modular processing unit 90, if so desired.

Fifth, passive cooling systems, such as a natural convection system, may be used to dissipate heat from the processing unit rather than requiring some type of mechanical or forced air system, such as a blower or fan. Of course, such forced air systems are also contemplated for use in some particular embodiments. It should be noted that these advantages are not all inclusive. Other features and advantages will be recognized by one skilled in the art.

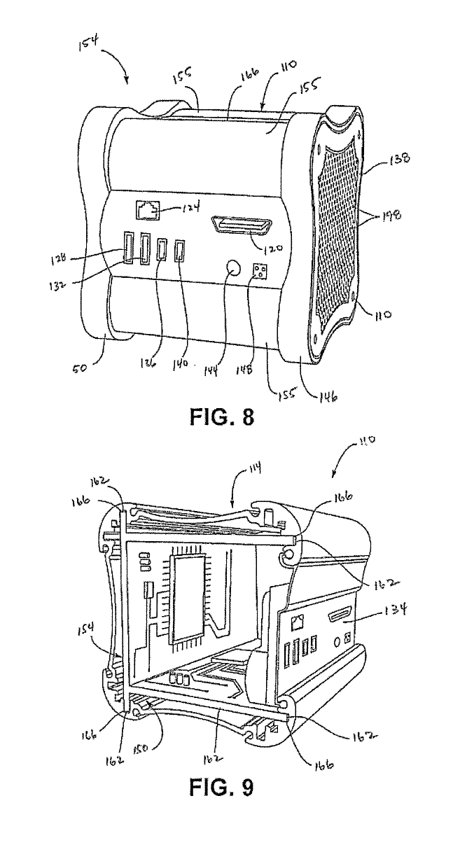

With reference to FIG. 8, shown is modular processing unit 90, and particularly encasement module 100, in an assembled state having first end plate 138 and second end plate 142 (not shown), first and second end caps 146 and 150, inserts 166, 170 (not shown), and 174 (not shown), as well as dynamic backplane 134 attached thereto. Dynamic backplane 134 is designed to comprise the necessary ports and associated means for connecting that are used for coupling various input/output devices and power cords to modular processing unit 90 to enable it to function, especially in a workstation environment. While all the available types of ports are not specifically shown and described herein, it is intended that any existing ports, along with any other types of ports that come into existence in the future, or even ports that are proprietary in nature, are to be compatible with and capable of being designed into and functional with modular processing unit 90. Preferably, this is accomplished by designing a different and interchanging backplane 134 as needed.

Specifically, dynamic backplane 134 comprises DVI Video port 120, 10/100 Ethernet port 124, USB ports 128 and 132, SATA bus ports 136 and 140, power button 144, and power port 148. A proprietary universal port is also contemplated that is used to electrically couple two processing units together to increase the processing capabilities of the entire system and to provide scaled processing as identified and defined herein. One ordinarily skilled in the art will recognize the various ports that may be utilized with the processing unit of the present invention.

The highly dynamic, customizable, and interchangeable backplane 134 provides support to peripherals and vertical applications. In the illustrated embodiment, backplane 134 is selectively coupled to encasement 100 and may include one or more features, interfaces, capabilities, logic and/or components that allow processing unit 90 to be dynamically customizable. Dynamic backplane 134 may also include a mechanism that electrically couples two or more modular processing units together to increase the processing capabilities of the entire system as indicated above, and to provide scaled processing as will be further disclosed below.

Those skilled in the art will appreciate that backplane 134 with its corresponding features, interfaces, capabilities, logic and/or components are representative only and that embodiments of the present invention embrace back planes having a variety of different features, interfaces, capabilities and/or components. Accordingly, modular processing unit 90 is dynamically customizable by allowing one back plane to be replaced by another back plane in order to allow a user to selectively modify the logic, features and/or capabilities of modular processing unit 90.

Moreover, embodiments of the present invention embrace any number and/or type of logic and/or connectors to allow use of one or more modular processing units in a variety of different environments. For example, some environments may include vehicles (e.g., cars, trucks, motorcycles, etc.), hydraulic control systems, structural, and other environments. The changing of data manipulating system(s) on the dynamic back plane allows for scaling vertically and/or horizontally for a variety of environments.

It should be noted that in an embodiment, the design and geometric shape of encasement module 100 provides a natural indentation for the interface of these ports. This indentation is shown in FIG. 8. Thus, inadvertent dropping or any other impacts to modular processing unit 90, and encasement module 100, will not damage the system as these ports are protected via the indentation formed within the dynamic back plane. First and second end caps 146 and 150 also help to protect the system from damage.

Power button 144 has three states—system on, system off, and system standby for power boot. The first two states, system on and system off, dictate whether modular processing unit 90 is powered on or powered off, respectively. The system standby state is an intermediary state. When power is turned on and received, the system is instructed to load and boot the operating system supported on modular processing unit 90. When power is turned off, modular processing unit 90 will then interrupt any ongoing processing and begin a quick shut down sequence followed by a standby state where the system sits inactive waiting for the power on state to be activated.

In this preferred embodiment, modular processing unit 90 also comprises a unique system or assembly for powering up the system. The system is designed to become active when a power cord and corresponding clip is snapped into the appropriate port located on dynamic backplane 134. Once the power cord and corresponding clip is snapped into power port 148 the system will fire and begin to boot. The clip is important because once the power source is connected and even if the power cord is connected to the leads within power port 148, modular processing unit 90 will not power on until the clip is snapped in place. Indicators may be provided, such as on the monitor, that warn or notify the user that the power cord is not fully snapped in or properly in place.

SATA bus ports 136 and 140 are designed to electronically couple and support storage medium peripheral components, such as CD-ROM drives, and hard drives.

USB ports 128 and 132 are designed to connect peripheral components like keyboards, mice, and any other peripheral components, such as 56k modems, tablets, digital cameras, network cards, monitors, and others.

The present invention also contemplates snap-on peripherals that snap onto dynamic back plane and couple to the system bus of modular processing unit 90 through a snap on connection system. As stated, other ports and means for connecting peripheral or input/output devices may be included and incorporated into modular processing unit 90 as recognized by one skilled in the art. Therefore, the particular ports and means for connecting specifically identified and described herein are intended to be illustrative only and not limiting in any way.

With reference to FIG. 9, the present invention modular processing unit 90 comprises a proprietary computer processing system 150, with encasement module 100 comprising a unique design and structural configuration for housing processing system 150 and the electrical printed circuit boards designed to operate and be functional within modular processing unit 90.

Essentially, processing system 150 includes one or more electrical printed circuit boards, and preferably three electrical printed circuit boards, oriented and formed in a tri-board configuration 152 as shown in FIG. 8. Processing system 150, and particularly tri-board configuration 152, comprises first electrical printed circuit board 154, second electrical printed circuit board 158, and third electrical printed circuit board 162 coupled to and housed within encasement module 100 as shown. Processing system 150 further comprises at least one central processor and optionally one or more other processors designed to perform one or more particular functions or tasks. Processing system 150 functions to execute the operations of modular processing unit 90, and specifically to execute any instructions provided on a computer readable media, such as on a memory device, a magnetic hard disk, a removable magnetic disk, a magnetic cassette, an optical disk (e.g. hard drives, CD-ROM's, DVD's, floppy disks, etc.), or from a remote communications connection, which may also be viewed as a computer readable medium. Although these computer readable media are preferably located exterior to or without modular processing unit 90, processing system 150 functions to control and execute instructions on such devices as commonly known, the only difference being that such execution is done remotely via one or more means for electrically connecting such peripheral components or input/output devices to modular processing unit 90.

First, second, and third electrical printed circuit boards 154, 158, and 162 are supported within main support chassis 114 using means for engaging or coupling or supporting electrical printed circuit boards. In the embodiment shown in FIG. 8, means for engaging electrical printed circuit boards comprises a series of board receiving channels 62 located in each junction center of encasement module 100. Board receiving channels 62 are adapted to accept an end portion 166 of an electrical printed circuit board. Several orientations may exist for placing electrical printed circuit boards within encasement module 100, but preferably end portion 166 of first electrical printed circuit board 154 fits within board receiving channel 162 located adjacent first wall support 118. End portions 166 of second and third electrical printed circuit boards 158 and 162 fit in a similar manner within board receiving channel 162 located adjacent second and third wall supports 122 and 126, respectively, to comprise the orientation as shown in FIG. 9.

Board configuration 152 and printed circuit boards are not supported by and preferably do not rest upon any of the wall supports of primary chassis 114. Each of the electrical printed circuit boards are specifically supported within primary chassis 114 by board receiving channels 62 located within junction centers. Primary chassis 114 is designed this way to provide a gap or space between each of the electrical printed circuit boards and the opposing wall supports to allow for the proper airflow within modular processing unit 90 according to the unique natural convection cooling properties provided herein. As such, each radius of curvature calculated for each wall support is designed with this limitation in mind.

Board configuration 152 provides significant advantages over prior art board configurations. As one advantage, board configuration 152 is configured in three multi-layer main boards instead of one main board as found in conventional computer systems. In addition, less real estate is taken up as the boards are able to be configured within different planes.

Another advantage is in the way two of the main boards couple to a third main board. By coupling each of the first, second, and third electrical printed circuit boards 154, 158, and 162 together in this manner, the chance for detachment of each of these boards from their proper place within primary chassis 114 and encasement module 100 is significantly decreased. In virtually any circumstance and condition modular processing unit 90 is exposed to, tri-board configuration 152 will remain intact and in working order, thus maintaining or preserving the integrity of the system. This is true even in impact and applied loading situations.

Preferably, first and third electrical printed circuit boards 154 and 162 are attached to third electrical printed circuit board 158 during manufacture and prior to board configuration 152 being placed within encasement module 100. Once board configuration 152 is assembled it is inserted into and secured to main support chassis 114 as shown. It should be noted that not all of board receiving channels 62 are necessarily utilized.

FIG. 9 illustrates the preferred embodiment, wherein only four of these channels are used to support the respective end portions of the electrical printed circuit boards. However, FIG. 9 is only illustrative of a one exemplary embodiment. Other configurational designs for processing system 150 are contemplated. For example, modular processing unit 90 could comprise one board only, or two or more boards. Moreover, processing system 150 may comprise a layered design configuration, in which the included printed circuit boards exist in a multi-planar configuration. One skilled in the art will recognize the several configurations and possibilities.

In addition to the many advantages discussed above, the present invention features other significant advantages, one of which is that due to encasement module 100 comprising a full metal chassis or a main support chassis 114, there is very little or no radiation emission in the form of electromagnetic interference (EMI). This is in large part due to the material properties, the small size, the thickness of the structure, and the close proximity of the processing components in relation to the structural components of encasement module 100. Whatever EMI is produced by the processing components is absorbed by encasement module 100, no matter the processing power of the processing components.

Another significant advantage is that encasement module 100 enables a much cleaner, more sterile interior than prior art computer encasement designs. Because of the design of encasement module 100, particularly the small size, ventilation ports, and the heat dissipating properties, it is very difficult for dust particles and other types of foreign objects to enter the encasement. This is especially true in a liquid cooled model, wherein the entire encasement may be sealed. A more sterile interior is important in that various types of foreign objects or debris can damage the components of and/or reduce the performance of modular processing unit 90.

Although modular processing unit 90 relies on natural convection in one exemplary embodiment, the natural influx and efflux of air during the natural convection process significantly reduces the influx of dust particles or other debris into modular processing unit 90 because there is no forced influx of air. In the natural convection cooling system described herein, air particles enter the interior of encasement module 100 according to natural principles of physics, and are less apt to carry with them heavier foreign object as there is less force to do so. This is advantageous in environments that contain such heavier foreign objects as most environments do.

The unique cooling methodology of modular processing unit 90 will allow it to be more adaptable to those environments prior related encasements were unable to be placed within.

Still another significant advantage of the present invention modular processing unit 90 is its durability. Because of its compact design and radius-based structure, encasement module 100 is capable of withstanding large amounts of impact and applied forces, a feature which also contributes to the ability for modular processing unit 90 to be adaptable to any type of conceivable environment. Encasement module 100 can withstand small and large impact forces with little effect to its structural integrity or electrical circuitry, an advantage that is important as the small size and portability of modular processing unit 90 lends itself to many conceivable environments, some of which may be quite harsh.

In addition to the structural components of encasement module 100 being very durable, the electrical printed circuit design board and associated circuitry is also extremely durable. Once inserted, the printed circuit boards are very difficult to remove, especially as a result of inadvertent forces, such as dropping or impacting the encasement. Moreover, the boards are extremely light weight, thus not possessing enough mass to break during a fall. Obviously though, encasement 100 is not entirely indestructible. In most circumstances, encasement module 100 will be more durable than the board configurations, therefore the overall durability of modular processing unit 90 is limited by the board configuration and the circuitry therein.

In short, encasement module 100 comprises a high level of durability not found in prior related encasement designs. Indeed, these would break, and often do, at very slight impact or applied forces. Such is not so with modular processing unit 90 described herein.

The durability of encasement module 100 is derived from two primary features. First, encasement module 100 is preferably built with radiuses. Each structural component, and their designs, are comprised of one or more radiuses. This significantly adds to the strength of encasement module 100 as a radius-based structure provides one of the strongest designs available. Second, the preferred overall shape of encasement module 100 is cubical, thus providing significant rigidness. The radius-based structural components combined with the rigidness of the cubical design, provide a very durable, yet functional, encasement.

The durability of the individual processing units/cubes allows processing to take place in locations that were otherwise unthinkable with traditional techniques. For example, the processing units can be buried in the earth, located in water, buried in the sea, placed on the heads of drill bits that drive hundreds of feet into the earth, mounted on unstable surfaces, mounted to existing structures, placed in furniture, etc. The potential processing locations are endless.

The processing unit of the present invention further features the ability to be mounted to, or to have mounted onto it, any structure, device, or assembly using means for mounting and means for engaging an external object (each preferably comprising slide receiver 182, as existing on each wall support of main support chassis 114). Any external object having the ability to engage modular processing unit 90 in any manner so that the two are operably connected is contemplated for protection herein. In addition, one skilled in the art will recognize that encasement module 100 may comprise other designs or structures as means for engaging an external object other than slide receivers 182.

Essentially, the significance of providing mountability to processing unit, no matter how this is achieved, is to be able to integrate modular processing unit 90 into any type of environment as discussed herein, or to allow various items or objects (external objects) to be coupled or mounted to modular processing unit 90. The unit is designed to be mounted to various inanimate items, such as multi-plex processing centers or transportation vehicles, as well as to receive various peripherals mounted directly to modular processing unit 90, such as a monitor or LCD screen.

In at least some embodiments, the mountability feature is designed to be a built-in feature, meaning that modular processing unit 90 comprises means for engaging an external object built directly into its structural components. Both mounting using independent mounting brackets (e.g. those functioning as adaptors to complete a host-processing unit connection), as well as mounting directly to a host (e.g. mounting the unit in a car in place of the car stereo) are also contemplated for protection herein.

Another capability of modular processing unit 90 is its ability to be mounted and implemented within a super structure, such as a Tempest super structure, if additional hardening of the encasement module is effectuated. In such a configuration, modular processing unit 90 is mounted within the structure as described herein, and functions to process control the components or peripheral components of the structure. Modular processing unit 90 also functions as a load bearing member of the physical structure if necessary. All different types of super structures are contemplated herein, and can be made of any type of material, such as plastic, wooden, metal alloy, and/or composites of such.

Other advantages include a reduction in noise and heat and an ability to introduce customizable “smart” technology into various devices, such as furniture, fixtures, vehicles, structures, supports, appliances, equipment, personal items, etc. (external object). These concepts are discussed in detail below.

As provided above, the present invention processing unit is unlike any other prior related computing processing system in that, because of its unique design and configuration, the processing unit may be associated with, integrated into, or otherwise operably connected with an external object to introduce customizable “smart” technology into the external object, thus allowing the external object to perform many smart functions that it would otherwise not be able to perform. In addition, the robust customizable computing system may be applicable to various identified types of enterprise applications, such as computers and computing systems, electronics, home appliances, applications in various industries, etc. This section details the ability of the processing unit described above to provide such robust customizable computing systems and their applicability in several exemplary enterprise applications.

Embodiments of the present invention feature the ability for integrating, incorporating, or otherwise operably connecting a proprietary processing unit into any conceivable system, device, assembly, apparatus, or object (collectively referred to as an “external object”) to introduce intelligence into the external object or to perform one or more computing functions for the external object or to fulfill other functions with respect to the external object as recognized by those skilled in the art. By doing so, the item essentially becomes or is transformed into a “smart” item, meaning that the external object may perform many functions and tasks not hitherto possible. Specifically, through the operable connection of the processing unit to an external object, the external object becomes capable of being much more functional than without a processing unit present. For instance, if an electronic external object, the processing unit can integrate with the circuitry, if any, of the electronic external object to provide added computing and processing power. If incorporating into a mechanical assembly or device or system, the addition of a processing unit may allow the mechanics to be controlled by computer or more specifically controlled, or may allow several other computing functions to be possible. If incorporated into an existing structure, the addition of a processing unit may allow the structure to perform computing functions not otherwise possible. Moreover, the processing unit may serve as a support component to a structure, or support a load itself. Essentially, there is no limit to the types of functions that the external object may be caused to perform as a result of the processing unit being operably connected thereto. However, such capabilities will be limited by the design and processing capabilities built into the processing unit as will be recognized by one of ordinary skill in the art. This ability or capability to be operably connected with various external objects is a unique feature not found in conventional prior related computing devices and is made possible by the design, structure, and processing capabilities combination of modular processing unit 90.

Incorporating or operably connecting a processing unit into an external object may be accomplished with the processing unit physically attached or not. In some instances it may not be desirable to physically attach the unit. Regardless of the type of physical attachment, the processing unit is operably connected to the external object, meaning that the processing unit is somehow functional with the external object itself to provide computing capabilities to or for the external object. As stated, this may be through existing or built-in circuitry, or installed circuitry, or through other means.

In one exemplary embodiment, modular processing unit 90 is physically connected to the external object. The physical connection is made possible due to the “slide-on” or “snap-on” capabilities of modular processing unit 90. By “slide-on,” and “snap-on” it is meant that modular processing unit 90 may accept various brackets, mounts, devices, etc. by sliding or snapping them into a suitable acceptor or receiver, respectively, located on modular processing unit 90, such as slide receivers 182. In addition, an entire modular processing unit 90 may be slid or snapped into another structure using the same receivers. Essentially, the present invention provides means of allowing modular processing unit 90 to accept different peripheral items, or to be incorporated into another structure. In other embodiments, the particular methods and/or systems employed to mount the processing unit to an external object may be those well known in the art.

Having said this, the processing unit, due to its unique and proprietary design, can essentially function as the engine that drives and controls the operation of many components, structures, assemblies, equipment modules, etc.

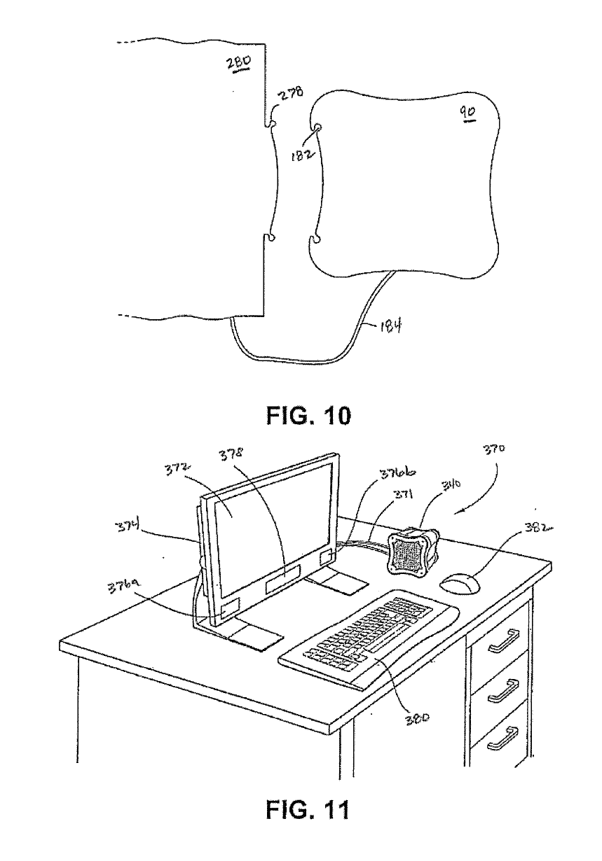

FIG. 10 illustrates one embodiment for coupling modular processing unit 90 to external object 280. In the embodiment shown, modular processing unit 90 is operably coupled in an electrical and physical manner to external object 280. Physical connection is achieved by locating engagement members 278 formed on external object 280 and fitting or inserting these into slide receivers 182 located on modular processing unit 90 (see discussion above with respect to FIG. 5). Inserting engagement members 278 into slide receivers 182 effectively functions to physically connect modular processing unit 90 to external object 280, such that processing unit may serve as a structural component (e.g., load bearing or non-load bearing) of the external object itself, or as the support for one or more external objects. Of course, as one ordinarily skilled in the art will recognize, other methods and systems may be used to physically connect processing unit to external object 280, each of which are intended to be covered and protected herein.

FIG. 10 further illustrates means for operably connecting modular processing unit 90 to external object 280 as comprising a connection cord connecting the circuitry present about or within external object 280 with that of modular processing unit 90. This is preferably done through one or more ports of modular processing unit 90.

The processing unit is capable of being arranged in countless ways to provide a robust customizable computing system. Several such systems are provided below for illustrative purposes. It should be noted that the following examples are not to be construed as limiting in any way, as one ordinarily skilled in the art will recognize the virtually endless conceivable arrangements and systems that may comprise one or more processing units to create a robust customizable computing system, as well as the many different types of enterprise applications that may utilize such a system.

With reference now to FIG. 11, a representative enterprise 370 is illustrated, wherein a dynamically modular processing unit 340 having a non-peripheral based encasement, is employed alone in a personal computing enterprise. In the illustrated embodiment, processing unit 340 includes power connection 371 and employs wireless technology with the peripheral devices of enterprise 370. The peripheral devices include monitor 372 having hard disk drive 374, speakers 376, and CD ROM drive 378, keyboard 380 and mouse 382. Those skilled in the art will appreciate that embodiments of the present invention also embrace personal computing enterprises that employ technologies other than wireless technologies.

Processing unit 340 is the driving force of enterprise 370 since it provides the processing power to manipulate data in order to perform tasks. The dynamic and customizable nature of the present invention allows a user to easily augment processing power. In the present embodiment, processing unit 340 is a 4-inch cube that utilizes thermodynamic cooling and optimizes processing and memory ratios. However, as provided herein, embodiments of the present invention embrace the use of other cooling processes in addition to or in place of a thermodynamic cooling process, such as a forced air cooling process and/or a liquid cooling process. Furthermore, while the illustrated embodiment includes a 4-inch cube platform, those skilled in the art will appreciate that embodiments of the present invention embrace the use of a modular processing unit that is greater than or less than a 3½-inch cube platform. Similarly, other embodiments embrace the use of shapes other than a cube.

In particular, processing unit 340 of the illustrated embodiment includes a 2 GHz processor, 1.5 G RAM, a 512 L2 cache, and wireless networking interfaces. So, for example, should the user of enterprise 370 determine that increased processing power is desired for enterprise 370, rather than having to purchase a new system as is required by some traditional technologies, the user may simply add one or more modular processing units to enterprise 370. The processing units/cubes may be selectively allocated by the user as desired for performing processing. For example, the processing units may be employed to perform distributive processing, each unit may be allocated for performing a particular task (e.g., one unit may be dedicated for processing video data, or another task), or the modular units may function together as one processing unit.

While the present example includes a processing unit that includes a 2 GHz processor, 1.5 G RAM, and a 512 L2 cache, those skilled in the art will appreciate that other embodiments of the present invention embrace the use of a faster or slower processor, more or less RAM, and/or a different cache. In at least some embodiments of the present invention, the capabilities of the processing unit depends on the nature for which the processing unit will be used.

While FIG. 11 illustrates processing unit 340 on top of the illustrated desk, the robust nature of the processing unit/cube allows for unit 340 to alternatively be placed in a non-conspicuous place, such as in a wall, mounted underneath the desk, in an ornamental device or object, etc. Accordingly, the illustrated embodiment eliminates traditional towers that tend to be kicked and that tend to produce sound from the cooling system inside of the tower. No sound is emitted from unit 340 as all internal components are solid states when convection cooling or liquid cooling is employed.

With reference now to FIG. 12, another example is provided for utilizing a modular processing unit in a computing enterprise. In FIG. 12, an ability of modular processing unit 340 to function as a load-bearing member is illustrated. For example, a modular processing unit may be used to bridge two or more structures together and to contribute to the overall structural support and stability of the structure or enterprise. In addition, a modular processing unit may bear a load attached directly to a primary support body. For example, a computer screen or monitor may be physically supported and the processing controlled by a modular processing unit. In the illustrated embodiment, monitor 390 is mounted to modular processing unit 340, which is in turn mounted to a stand 392 having a base 394.

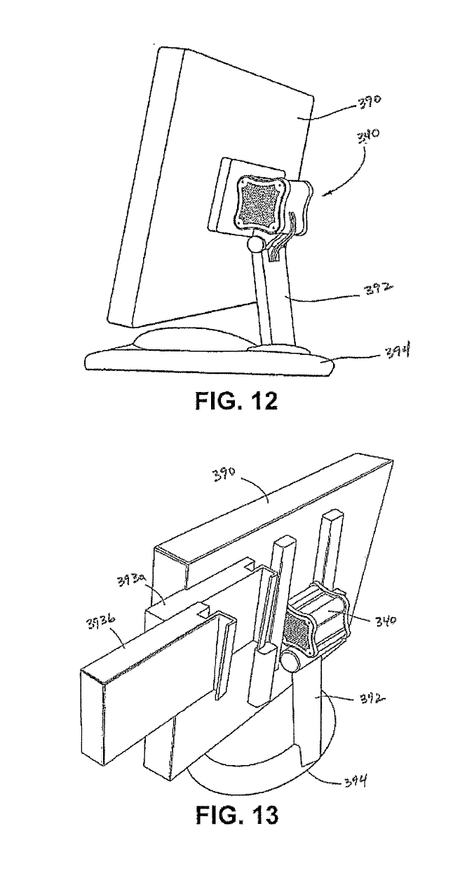

With reference now to FIG. 13, another representative enterprise is illustrated, wherein a dynamically modular processing unit 340 having a non-peripheral based encasement, is employed computing enterprise. In FIG. 13, the representative enterprise is similar to the embodiment illustrated in FIG. 12, however one or more modular peripherals are selectively coupled to the enterprise. In particular, FIG. 13 illustrates mass storage devices 393 that are selectively coupled to the enterprise as peripherals. Those skilled in the art will appreciate that any number (e.g., less than two or more than two) and/or type of peripherals may be employed. Examples of such peripherals include mass storage devices, I/O devices, network interfaces, other modular processing units, proprietary I/O connections; proprietary devices, and the like.

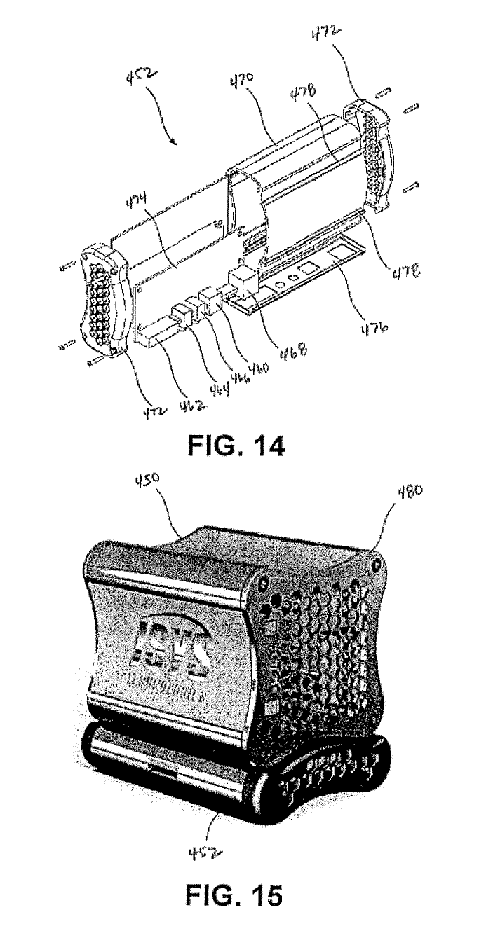

FIG. 14 illustrates another example of a dynamically modular processing unit. In FIG. 14, the dynamically modular processing unit is shown in an exploded perspective view of one illustrative embodiment of peripheral module 452. The peripheral module 452 includes a bus port 460 for connecting a bus (not shown) to be connected to the base module 450. In one example, the bus port 460 is a USB port, but as mentioned above, the bus may be any type of bus. The bus is used to drive input/output commands (e.g. keyboard, mouse, and video commands) between the base module 450 (FIG. 15) and the peripheral module 452, and faster buses simply allow more commands to pass between the modules, but only enough is required to take in inputs and display or otherwise output the outputs from the base module 450.

The peripheral module 452 also includes several other types of ports to allow the connection of the input/output devices 454. For example, the illustrated embodiment includes a video port 462, an audio input port 464, an audio output port 466, and some additional bus (e.g. USB) ports 468. The audio input port 464 and the audio output port 466 of this embodiment allow this embodiment to be used, for example, in a call center. The USB or other bus ports 468 may be used to connect other input/output devices such as a keyboard and mouse. The illustrated ports are intended to be only illustrative and not restrictive. The peripheral module 452 uses and manages these various ports to create a user experience essentially as a session on the base module 450.

FIG. 14 shows how the peripheral module 452 may be constructed. As may be seen in this Figure, the peripheral module 452 includes an outer structural shell 470 and two end caps 472. The structural shell 470 and end caps 472 serve to enclose and protect a system board 474 of the peripheral module 452. The structural shell 470 may be made of a variety of materials, including plastics and metals, including aluminum and/or metal alloys, and may be formed in a way so as to provide structural functions as discussed in the related applications. Additionally, the structural shell 470 may be formed so as to mate with the structure of the base module 450 as is illustrated in FIG. 15. As shown in FIG. 14, the various ports discussed above are attached to the system board 474. A port cover plate 476 may serve to cover any gaps between the different ports.

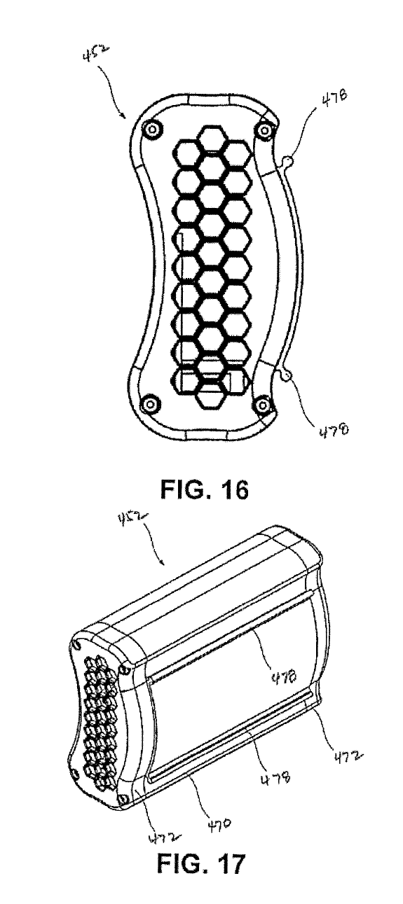

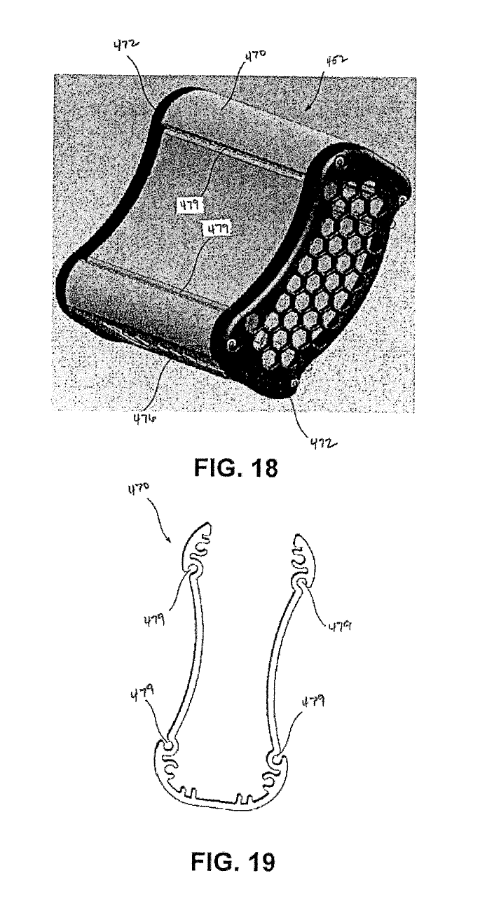

FIGS. 16 and 17 show end and perspective views of the peripheral module 452, respectively. In these views, some features of the structural shell 470 are visible that show one way in which mating with the base module 450 or other peripheral modules 452 may be accomplished. As may be seen in FIGS. 16 and 17, the structural shell 470 may be formed (e.g. extruded) to have a pair of mating protrusions 478 on one major side of the peripheral module 452. As may be seen in FIG. 18, the opposite major side of the structural shell 470 in this embodiment is formed to have a corresponding pair of mating channels 479 that can accept the mating protrusions 478. As may also be seen in FIGS. 16 through 18, the end caps 472 do not include either the mating protrusions 478 or the corresponding mating channels 479. The base module 450 includes corresponding mating channels 479 on at least one of its sides, and possibly on as many as three of its sides (but again, not on its end caps).

To structurally attach the peripheral module 452 to the base module 50 in the manner shown in FIG. 15, an end cap 480 of the base module 450 is removed (tamper-resistant fasteners may be used to deter theft or vandalism), and the mating protrusions 478 of the peripheral module 452 are slidingly engaged with the corresponding mating channels 479 of the base module 450. The peripheral module 452 slides until it is fully mated with the base module 450. The end cap 480 of the base module 450 is reattached to the base module 450 and thereby locks the peripheral module 452 to the base module 450. Additional peripheral modules 452 or other components may be attached to the system using the mating channels 479 of either the peripheral module 452 or of other sides of the base module 450 as desired, with the corresponding end cap (472 or 480) being removed to facilitate such attachment.

The illustrated embodiments shown in FIGS. 14-18 are merely illustrative of ways that embodiments may be constructed to permit structural connections between modules and with other devices. Thus, for example, while the illustrated peripheral module 452 has mating protrusions 478 on one major side and mating channels 479 on another major side, another embodiment may have mating channels 479 on both major sides, as illustrated in the end view depiction of an alternate outer structural shell 470 shown in FIG. 19.

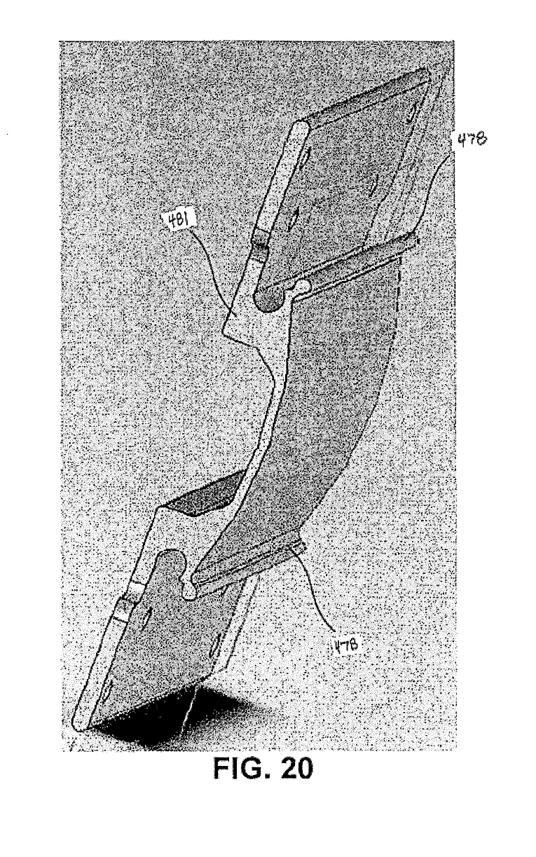

The structural shell 470 of the peripheral module 452 may be load bearing as disclosed in one or more of the related applications. The peripheral module 452 may therefore be used as a mount from which to hang a monitor or other device, may be embedded or mounted in a wall, may be a part of a frame, and may perform any of the structural functions disclosed in the related applications. For example, a plate may be mounted to a wall and another plate may be mounted to a monitor, and the two plates may be connected together through the structural features of the peripheral module 452. One illustrative embodiment of a plate 481 is shown in FIG. 20. The plate 481 is an extruded and cut plate that has mating protrusions 478 similar to those discussed above, although it could alternatively have mating channels 479. The plate 481 could be mounted to any of a variety of modules discussed herein such as the peripheral module 452. Thus, the peripheral module 452 may essentially serve as an intelligent mounting bracket.

A system including peripheral modules 452 differs somewhat from a system composed entirely of base modules 450, even if the base modules 450 are of varying types. For example, as disclosed in the related applications, base modules 450 may be connected to each other and may include varying features (such as one or more cubes containing a GPU instead of a CPU) so as to increase the processing abilities of the combined units. For example, some combinations of units may essentially work together to form a supercomputer or provide supercomputer-like functions. In contrast, the addition of peripheral modules 452 to the system (regardless of the number and configuration of base modules 450) primarily functions to allow the distribution of computing capabilities of the base module(s) 450 through the peripheral modules 452. (As discussed above, peripheral modules 452 having more than a minimum computing capability may be used and may therefore add some processing capability to the system, and additional system resources (e.g. printers, mass storage devices, web cameras and the like) may be attached to the peripheral modules 452 and thus become available to the combined system.)

Thus, the addition of peripheral modules 452 to the system allows resources to be shared to the human element by driving graphical user interfaces (GUIs) using that power. Thus, the users are thereby permitted to view and manipulate data that is available on the one or more connected base modules. The peripheral modules 452 need not be designed to do work at the peripheral modules 452 other than passing data to and from the input/output devices 454. The peripheral modules 452 instead permit the accessing of a GUI session on the base module 450, thereby providing access to the data, programs, and other resources available on the base module 450. The primary computing functions are handled by the base module(s) 450, and each peripheral module 452 serves to open a window to access the resources of the base module(s) 450.

### Representative Mounting Brackets

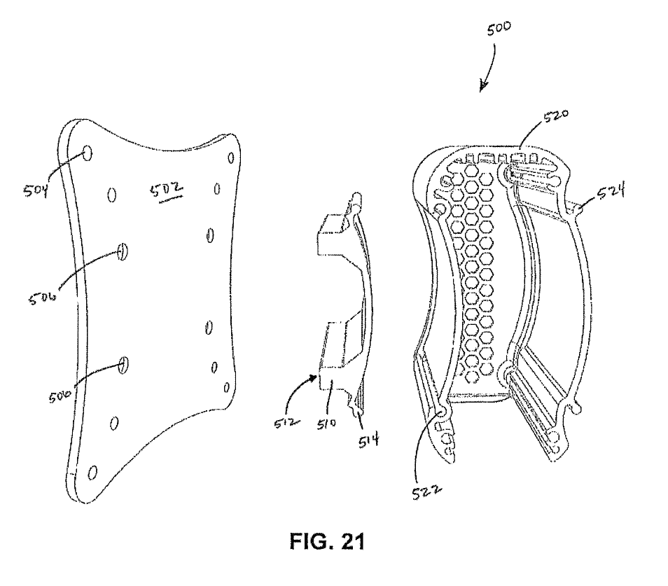

FIG. 21 illustrates a representative mounting system 500, which includes mounting plate 502, mounting connector 510 and chassis 520. Mounting plate 502 includes apertures that are configured to align with a VESA mount on a monitor, television, or other device. Alternatively, plate 520 can be used to be secured to any surface or object. Plate 502 includes apertures that are aligned to apertures 512 in connector 510. Further, connector 514 includes protrusions that are configured to slide into channels 522 of chassis 520, which can be any type of modular processing unit (including a base module or a peripheral module). Further, chassis 520 includes protrusions 524 to be able to slide into channels of another chassis of a modular processing unit.

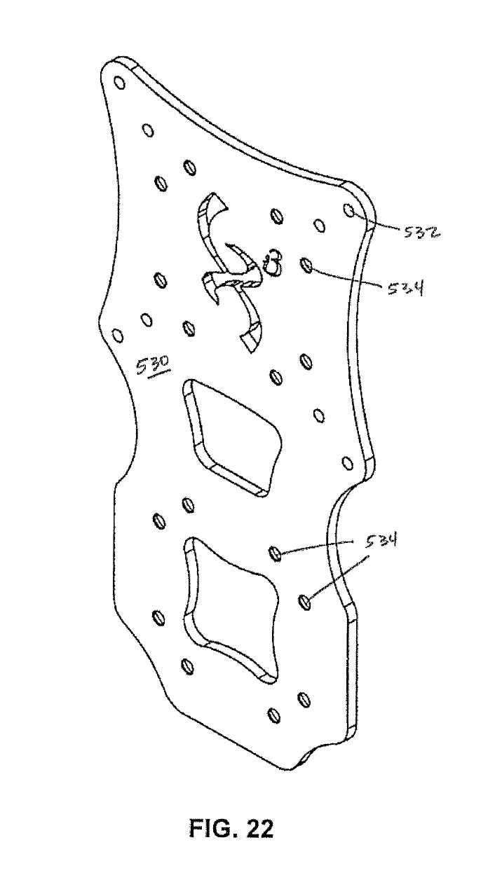

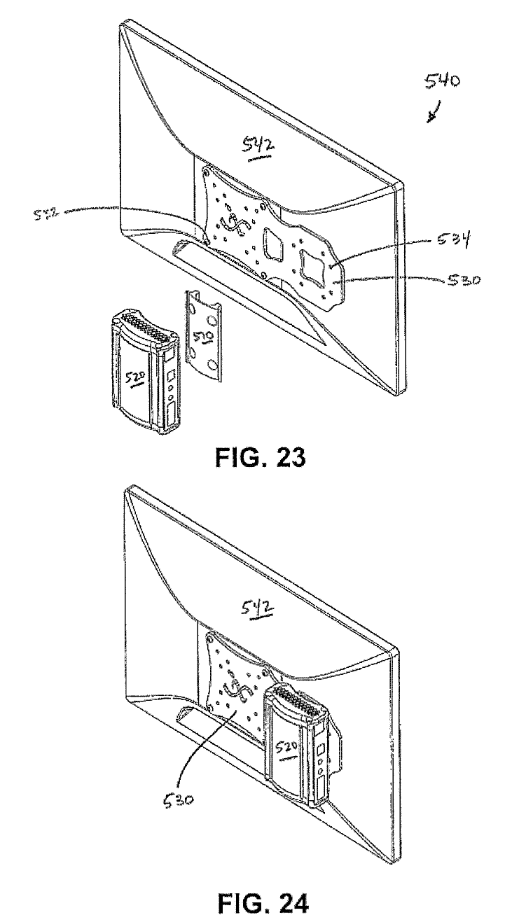

FIG. 22 illustrates another representative mounting bracket 530, which can comprise any metal, metal alloy, aluminum, aluminum alloy, nylon, hybrid material, polymer, or other durable material. Bracket 530 includes apertures 532 that are configured to align with a VESA mount on a monitor, television, or other device. Bracket 530 further includes apertures 534 that are configured to selectively mount one or more connectors 510 along with one or more corresponding modular processing units.

FIG. 23 illustrates a representative manner of mounting a modular processing unit. System 540 includes monitor 542 that has mounted thereon bracket 530 using the VESA mount apertures 532. Apertures 534 are used to mount connector 510 onto bracket 530, and modular processing unit 520 is mounted onto connector 510 using the channel/protrusion system. FIG. 24 illustrates an assembled view of the representative manner of mounting a modular processing unit of FIG. 23.

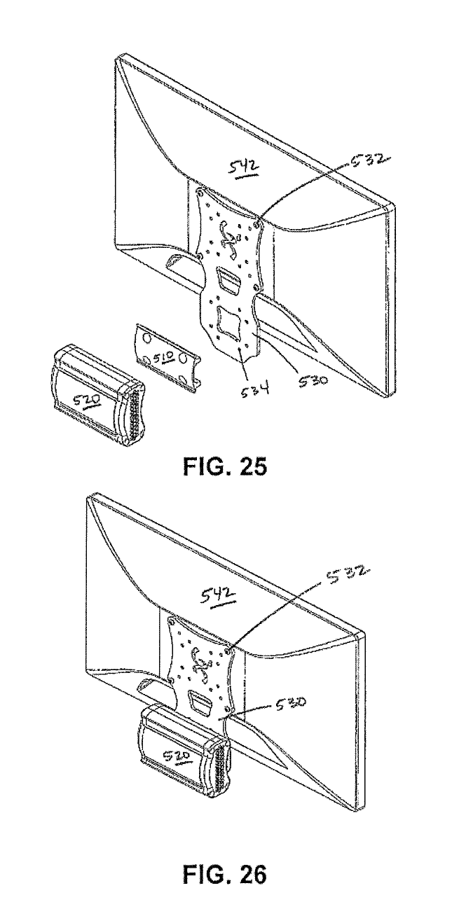

FIG. 25 illustrates another representative manner of mounting a modular processing unit, wherein bracket 530 is dynamic in that it allows connection to monitor 542 in a variety of orientations, namely in 90 degree orientations—rotated either clockwise or counterclockwise. FIG. 26 illustrates an assembled view of the representative manner of mounting a modular processing unit of FIG. 25.

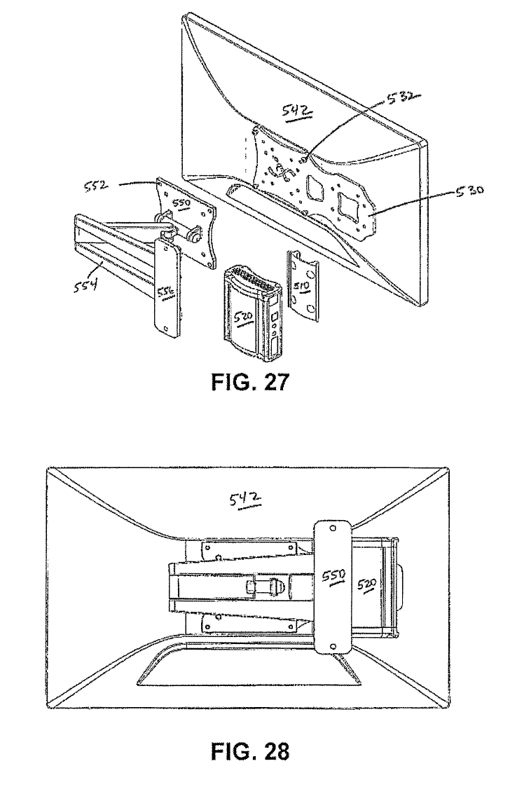

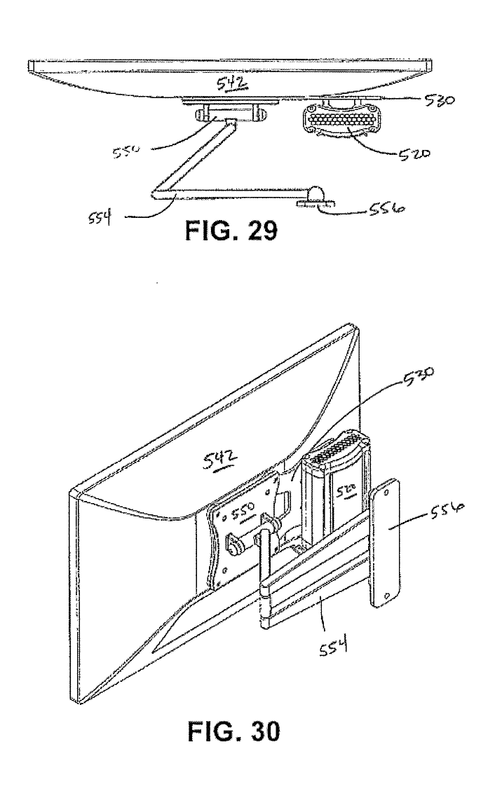

FIG. 27 illustrates another representative manner of mounting a modular processing unit, wherein monitor 542 has bracket 530 mounted thereon. Also mounted to bracket 530 is mounting arm 550, having corresponding VESA apertures 552, hinged arm 554, and surface 556. Moreover, connector 510 is used to mount modular processing unit 520 onto bracket 530. FIG. 28 illustrates an assembled view of the representative manner of mounting a modular processing unit of FIG. 27. FIG. 29 illustrates a top view of the representative manner of mounting a modular processing unit of FIG. 27. FIG. 30 illustrates a perspective view of the representative manner of mounting a modular processing unit of FIG. 27.

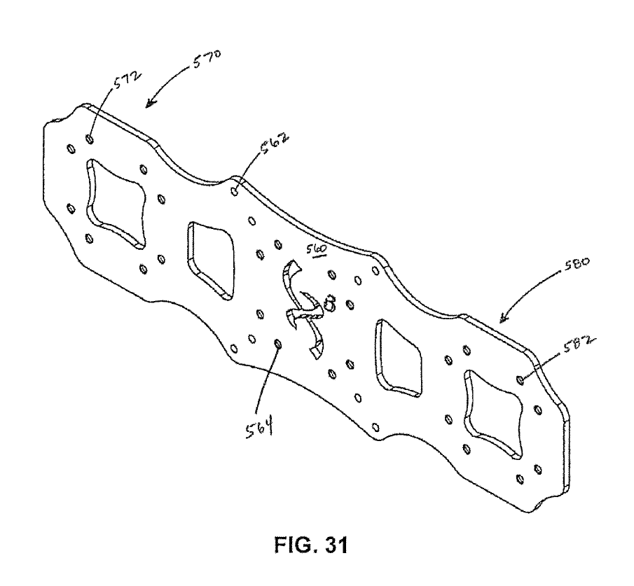

FIG. 31 illustrates a perspective view of another representative mounting bracket 560, which can comprise any metal, metal alloy, aluminum, aluminum alloy, nylon, hybrid material, polymer, or other durable material. Bracket 560 includes apertures 562 that are configured to align with a VESA mount on a monitor, television, or other device. Bracket 560 further includes apertures 564 that are configured to selectively mount one or more connectors 510 along with one or more corresponding modular processing units. Bracket 560 further includes end 570 having apertures 572 and end 580 having apertures 582. Apertures 572 and 582 are configured to selectively mount one or more connectors 510 along with one or more corresponding modular processing units.

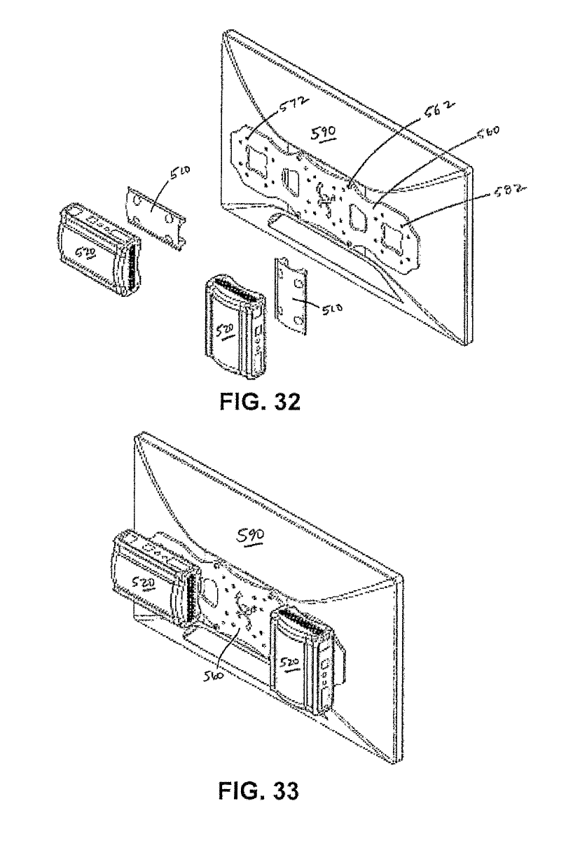

FIG. 32 illustrates a representative manner of mounting a modular processing unit. In FIG. 32, bracket 560 is mounted on monitor 590 using VESA mount apertures 562. Apertures 572 and 582 are used to mount connectors 510 onto bracket 560 using a screw or other attachment device. Further, protrusions on connectors 510 are slid into corresponding channels of modular processing units 520 to mount units 520 onto corresponding connectors 510. FIG. 33 illustrates an assembled view of the representative manner of mounting a modular processing unit of FIG. 32. Bracket 560 can be dynamically mounted onto television/monitor 590 in 90 degree increments of rotation.

### Connecting Modular Processing Units in Cabinets

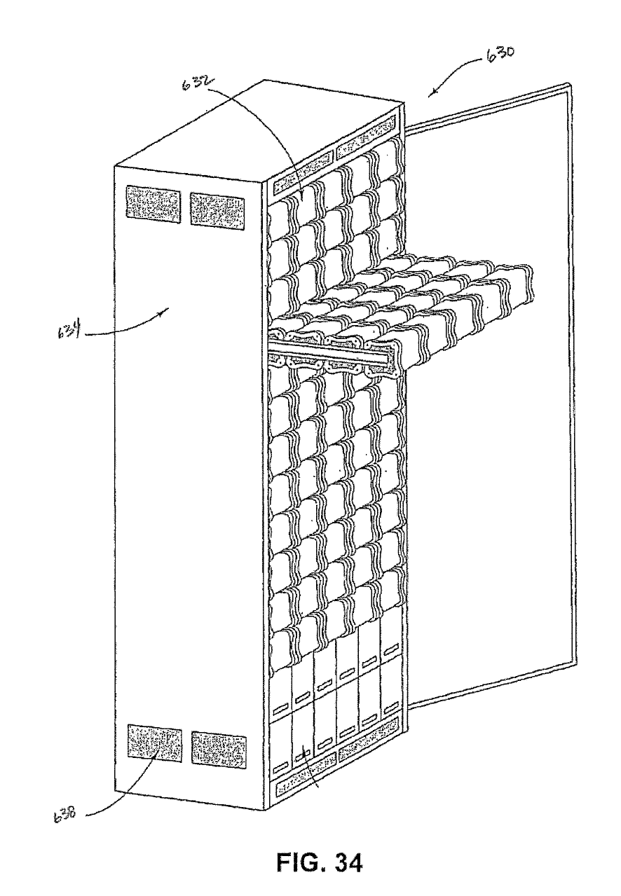

While FIG. 34 illustrates a cabinet 630 that includes drawers configured to receive the individual processing units 632, other embodiments of the present invention include the use of a mounting bracket that may be used in association with a processing unit to mount the unit onto a bar. The illustrated embodiment further includes a cooling system (not show) that allows for temperature control inside of cabinet 634, and utilizes vents 638.

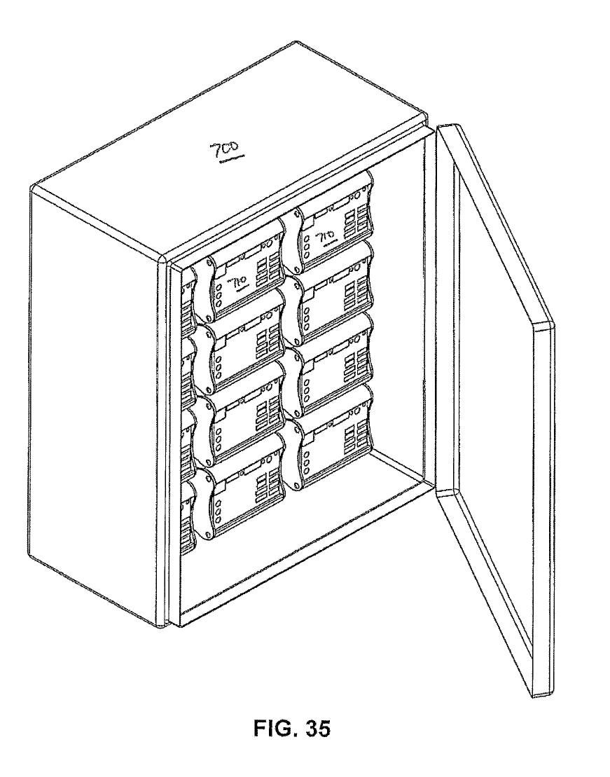

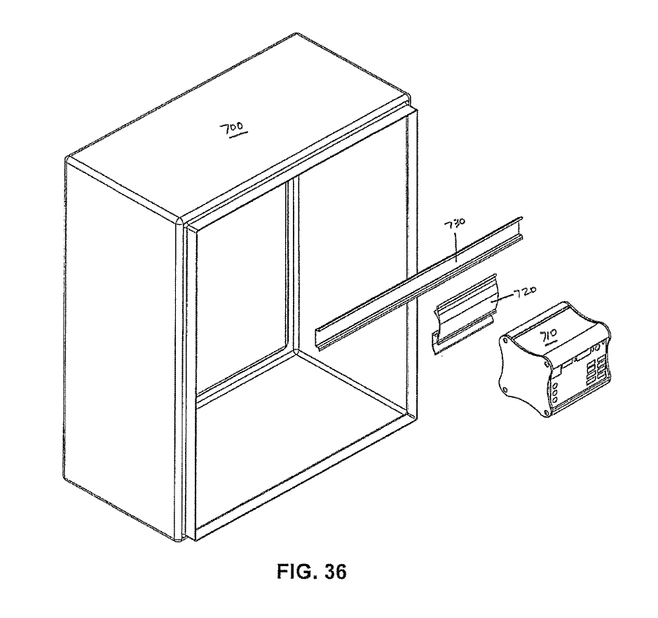

FIG. 35 illustrates another representative manner of mounting modular processing units in a rack, in a cabinet, or on a surface. In FIG. 35, modular processing units 710 are mounted into cabinet 700 using a DIN rail mounting system.

With reference to FIG. 36, cabinet 700 is a wall-mount cabinet that includes one or more DIN rails 730. A DIN rail connector 720, which comprises a polymer material, metal alloy, hybrid material, nylon or other material, is used to selectively mount a modular processing unit 710 onto the DIN rail.

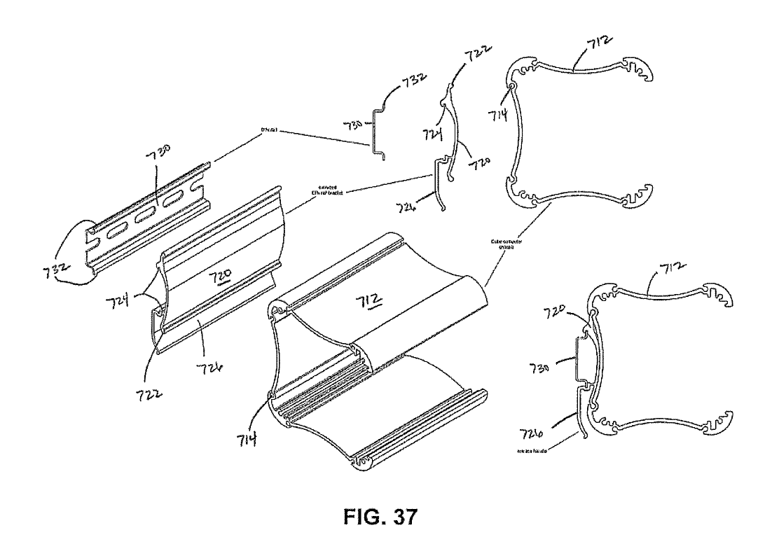

With reference to FIG. 37, the modular processing unit 710 comprises chassis 712 having channels 714. DIN rail connector 720 has protrusions 722 that are configured to slide into channels 714 and are secured upon securing endplates onto unit 710. DIN rail connector 720 further includes handle 726 that selectively causes connector 720 to flex in order to use surfaces 724 to clip onto surfaces 732 of DIN rail 730. By causing the handle 726 to come toward chassis 712, the connector can be selectively connector or disconnected from rail 730.

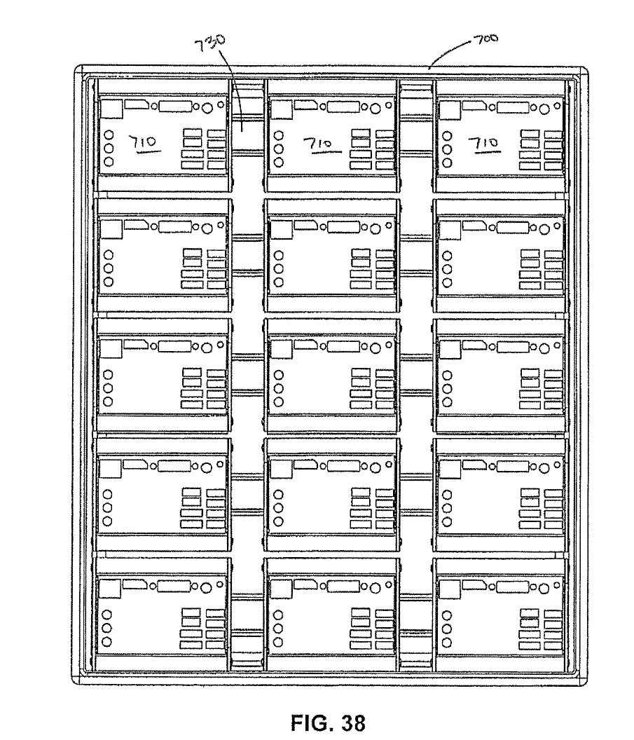

FIG. 38 illustrates another view of a representative DIN rail mounting system, wherein modular processing units 710 are mounted onto DIN rails 730, which are mounted in cabinet 700.

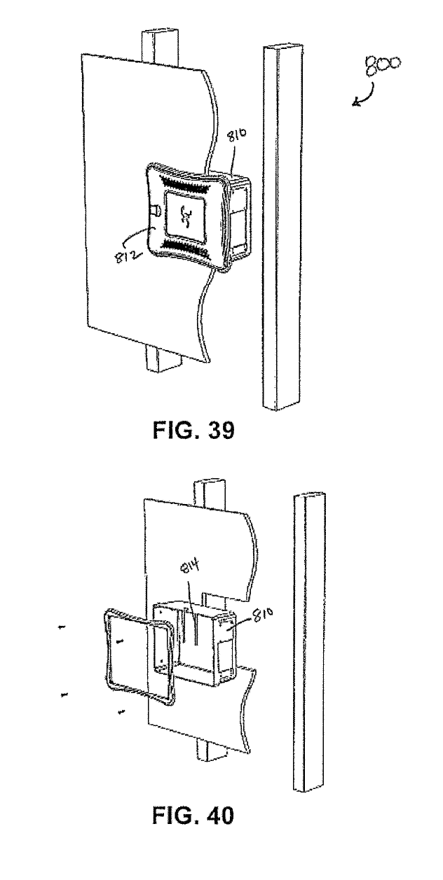

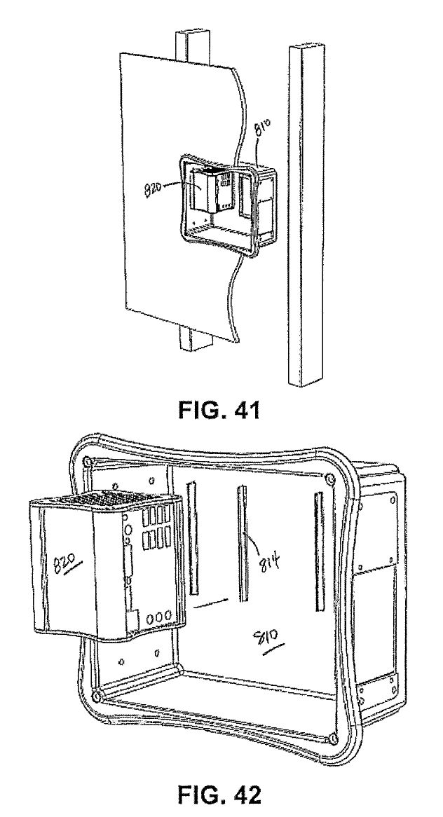

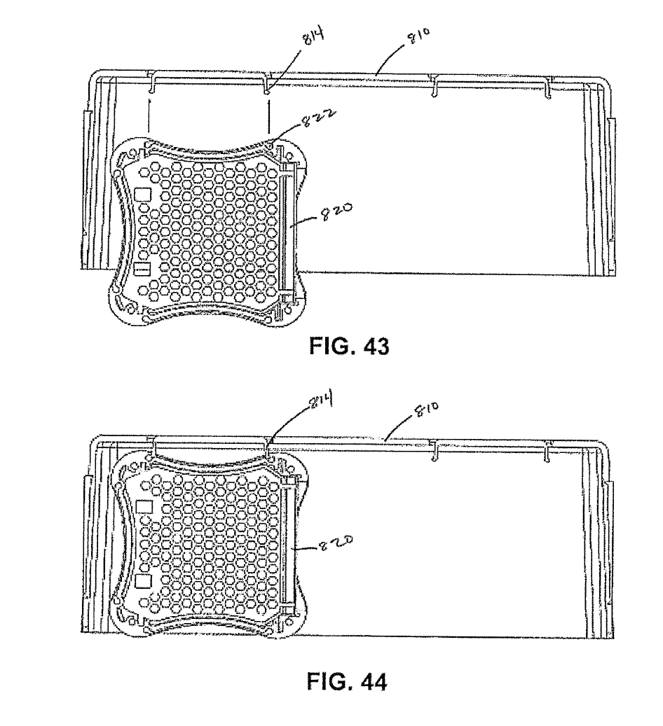

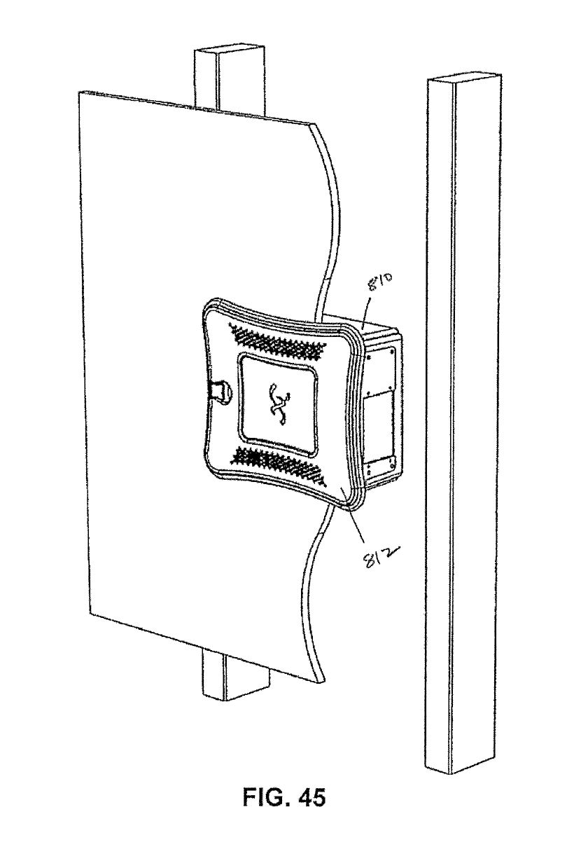

FIG. 39 illustrates another representative mounting system 800 having container 810 and lid 812. As illustrated in FIG. 40, container 810 includes pressure fit protrusions 814 that can be pushed into corresponding channels of a modular processing unit 820, as shown in FIGS. 41-45. Container 810 can comprise any material, including a polymer material, nylon, hybrid, metal, metal alloy, or other material. Thus, unit 820 can be easily mounted and/or removed from container 810.

The modular nature of the processing units/cubes is illustrated by the use of the processing units in the various representative enterprises illustrated. Embodiments of the present invention embrace chaining the units/cubes in a copper and/or fiber channel design, coupling the cubes in either series or parallel, designating individual cubes to perform particular processing tasks, and other processing configurations and/or allocations.

Each unit/cube includes a completely re-configurable motherboard. In one embodiment, the one or more processors are located on the back plane of the motherboard and the RAM modules are located on planes that are transverse to the back plane of the motherboard. In a further embodiment, the modules are coupled right to the board rather than using traditional sockets. The clock cycle of the units are optimized to the RAM modules.

While one method for improving processing powering an enterprise includes adding one or more additional processing units/cubes to the enterprise, another method includes replacing planes of the motherboard of a particular unit/cube with planes having upgraded modules. Similarly, the interfaces available at each unit/cube may be updated by selectively replacing a panel of the unit/cube. Moreover, a 32-bit bus can be upgraded to a 64-bit bus, new functionality can be provided, new ports can be provided, a power pack sub system can be provided/upgraded, and other such modifications, upgrades and enhancements may be made to individual processing units/cubes by replacing one or more panels.

Thus, as discussed herein, embodiments of the present invention embrace systems and methods for providing a dynamically modular processing unit. In particular, embodiments of the present invention relate to providing a modular processing unit that is configured to be selectively oriented with one or more additional units in an enterprise. In at least some embodiments, a modular processing unit includes a non-peripheral based encasement, a cooling process (e.g., a thermodynamic convection cooling process, a forced air cooling process, and/or a liquid cooling process), an optimized layered printed circuit board configuration, optimized processing and memory ratios, and a dynamic back plane that provides increased flexibility and support to peripherals and applications.

The present invention may be embodied in other specific forms without departing from its spirit or essential characteristics. The described embodiments are to be considered in all respects only as illustrative and not restrictive. The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes that come within the meaning and range of equivalency of the claims are to be embraced within their scope.

What is claimed is:

1. A system for selectively mounting a computer device, the system comprising:
a mounting system coupled to a chassis that is configured to house a processor, the mounting system further coupled to a surface such that the chassis is retained at the surface.
